(19) United States
(12) Patent Application Publication
(10) Pub. No.: US 2025/0301631 A1
(43) Pub. Date: Sep. 25, 2025

(54) SEMICONDUCTOR DEVICE

(71) Applicant: Kioxia Corporation, Tokyo (JP)

(72) Inventors: Ha HOANG, Yokkaichi (JP); Kazuhiro MATSUO, Kuwana (JP); Takuma DOI, Suzuka (JP); Masaya TODA, Yokkaichi (JP); Akihiro KAJITA, Yokkaichi (JP); Yasuyuki SONODA, Yokkaichi (JP)

(73) Assignee: Kioxia Corporation, Tokyo (JP)

(21) Appl. No.: 19/066,278

(22) Filed: Feb. 28, 2025

(30) Foreign Application Priority Data
Mar. 21, 2024 (JP) 2024-044676

(51) Int. Cl. H10B 12/00

(52) U.S. Cl. CPC H10B 12/33; H10B 12/036; H10B 12/05; H10B 12/50

(57) ABSTRACT

A semiconductor device includes a substrate, a first region, a second region, and a first insulating layer and a metal oxide layer disposed farther from the substrate than the first region. The first region includes a first transistor containing Si and a second insulating layer disposed between the first insulating layer and the metal oxide layer and the first transistor. The second region includes a second transistor containing oxide semiconductor and a third insulating layer disposed between the first insulating layer and the metal oxide layer and the second transistor. The metal oxide layer contains at least one element selected from the group consisting of Al, Hf, Zr, La, and Y and contains oxygen (O). The second insulating layer and the third insulating layer contain Si and oxygen (O). A density of the third insulating layer is higher than a density of the second insulating layer.

### CROSS-REFERENCE TO RELATED APPLICATIONS

This application is based upon and claims the benefit of Japanese Patent Application No. 2024-044676, filed on Mar. 21, 2024, the entire contents of which are incorporated herein by reference.

### BACKGROUND

### Field

Embodiments described herein relate generally to a semiconductor device.

### Description of the Related Art

There has been known a semiconductor device including an oxide semiconductor layer, a first wiring opposed to the oxide semiconductor layer, and a gate insulating film disposed between the oxide semiconductor layer and the first wiring.

### BRIEF DESCRIPTION OF THE DRAWINGS

FIG. 1 is a schematic circuit diagram illustrating a part of a configuration of a semiconductor device according to a first embodiment;

FIG. 2 is a schematic cross-sectional view illustrating a part of the configuration of the semiconductor device;

FIG. 3 is a schematic cross-sectional view illustrating a part of the configuration of the semiconductor device;

FIG. 4 is a schematic plan view illustrating a part of the configuration of the semiconductor device;

FIG. 5 is a schematic plan view illustrating a part of the configuration of the semiconductor device;

FIG. 6 is a schematic plan view illustrating a part of the configuration of the semiconductor device;

FIG. 7 is a schematic cross-sectional view for describing a method of manufacturing the semiconductor device;

FIG. 8 is a schematic cross-sectional view for describing the manufacturing method;

FIG. 9 is a schematic cross-sectional view for describing the manufacturing method;

FIG. 10 is a schematic cross-sectional view for describing the manufacturing method;

FIG. 11 is a schematic cross-sectional view for describing the manufacturing method;

FIG. 12 is a schematic cross-sectional view for describing the manufacturing method;

FIG. 13 is a schematic cross-sectional view for describing the manufacturing method;

FIG. 14 is a schematic cross-sectional view for describing the manufacturing method;

FIG. 15 is a schematic cross-sectional view for describing the manufacturing method;

FIG. 16 is a schematic cross-sectional view for describing the manufacturing method;

FIG. 17 is a schematic cross-sectional view for describing the manufacturing method;

FIG. 18 is a schematic cross-sectional view for describing the manufacturing method;

FIG. 19 is a schematic cross-sectional view for describing the manufacturing method;

FIG. 20 is a schematic cross-sectional view for describing the manufacturing method;

FIG. 21 is a schematic cross-sectional view for describing the manufacturing method;

FIG. 22 is a schematic cross-sectional view for describing the manufacturing method;

FIG. 23 is a schematic cross-sectional view for describing the manufacturing method;

FIG. 24 is a schematic cross-sectional view for describing the manufacturing method;

FIG. 25 is a schematic cross-sectional view for describing the manufacturing method;

FIG. 26 is a schematic cross-sectional view for describing the manufacturing method;

FIG. 27 is a schematic cross-sectional view for describing the manufacturing method;

FIG. 28 is a schematic cross-sectional view for describing a semiconductor device according to a comparative example;

FIG. 29 is a schematic cross-sectional view for describing effects of the semiconductor device according to the first embodiment;

FIG. 30 is a schematic cross-sectional view illustrating a part of a configuration of a modification 1 of the semiconductor device according to the first embodiment;

FIG. 31 is a schematic cross-sectional view illustrating a part of a configuration of a modification 2 of the semiconductor device according to the first embodiment;

FIG. 32 is a schematic cross-sectional view illustrating a part of a configuration of a semiconductor device according to a second embodiment;

FIG. 33 is a schematic cross-sectional view for describing a method of manufacturing the semiconductor device;

FIG. 34 is a schematic cross-sectional view for describing the manufacturing method;

FIG. 35 is a schematic cross-sectional view for describing the manufacturing method;

FIG. 36 is a schematic cross-sectional view for describing the manufacturing method;

FIG. 37 is a schematic cross-sectional view for describing the manufacturing method;

FIG. 38 is a schematic cross-sectional view for describing the manufacturing method;

FIG. 39 is a schematic cross-sectional view for describing effects of the semiconductor device according to the second embodiment;

FIG. 40 is a schematic cross-sectional view illustrating a part of a configuration of a semiconductor device according to a third embodiment;

FIG. 41 is a schematic cross-sectional view for describing effects of the semiconductor device;

FIG. 42 is a schematic cross-sectional view illustrating a part of a configuration of a semiconductor device according to a fourth embodiment; and

FIG. 43 is a schematic cross-sectional view for describing effects of the semiconductor device.

### DETAILED DESCRIPTION

A semiconductor device according to one embodiment includes a substrate; a first region disposed on one side in a first direction intersecting with a surface of the substrate with respect to the substrate; a second region disposed to be arranged with the first region in the first direction or a second direction intersecting with the first direction on the one side in the first direction with respect to the substrate; and a first insulating layer and a metal oxide layer disposed at a position farther from the substrate than the first region on the one side in the first direction. The first region includes: a first transistor having a first semiconductor layer containing silicon (Si); and a second insulating layer disposed between the first insulating layer and the first transistor and between the metal oxide layer and the first transistor. The second region includes: a second transistor having a second semiconductor layer containing an oxide semiconductor; and a third insulating layer disposed between the first insulating layer and the second transistor and between the metal oxide layer and the second transistor. The metal oxide layer contains at least one element selected from the group consisting of aluminum (Al), hafnium (Hf), zirconium (Zr), lanthanum (La), and yttrium (Y) and contains oxygen (O). Each of the second insulating layer and the third insulating layer contains silicon (Si) and oxygen (O). A density of the third insulating layer is higher than a density of the second insulating layer.

Next, the semiconductor devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, a predetermined direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the predetermined substrate. For example, a direction away from the predetermined substrate along the Z-direction is referred to as above and a direction approaching the predetermined substrate along the Z-direction is referred to as below. A lower surface and a lower end of a certain configuration mean a surface and an end portion at the predetermined substrate side of this configuration. An upper surface and an upper end of a certain configuration mean a surface and an end portion on a side opposite to the predetermined substrate of this configuration. A surface intersecting with the X-direction or the Y-direction is referred to as a side surface and the like.

In this specification, when referring to a “width”, a “length”, a “film thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### [Circuit Configuration]

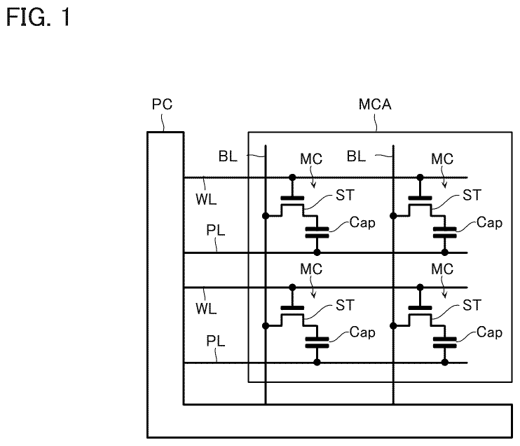

A semiconductor device according to a first embodiment includes, for example, a memory cell array MCA and a peripheral circuit PC as illustrated in FIG. 1.

The memory cell array MCA includes a plurality of bit lines BL, a plurality of word lines WL, a plurality of plate lines PL, and a plurality of memory cells MC that are connected to these plurality of bit lines BL, plurality of word lines WL, and plurality of plate lines PL. A plurality of memory cells MC connected to one word line WL are connected to the respective mutually different bit lines BL. A plurality of memory cells MC connected to one bit line BL are connected to the respective mutually different word lines WL.

Each of the memory cells MC includes a select transistor ST and a capacitor Cap that are connected in series between a bit line BL and a plate line PL.

The select transistor ST is a field-effect type transistor including a semiconductor layer that functions as a channel region, a gate insulating film, and a gate electrode. Each gate electrode of the select transistor ST is connected to a word line WL.

The capacitor Cap is a capacitor that includes a pair of electrodes and an insulating film. The capacitor Cap includes a memory portion.

The peripheral circuit PC includes, for example, a voltage generation circuit that generates an operating voltage and outputs the operating voltage to a voltage supply line, a decode circuit that electrically conducts a desired voltage supply line to each wiring (the bit lines BL, the word lines WL, and the plate lines PL) in the memory cell array MCA, a sense amplifier circuit that senses a current or a voltage of the bit lines BL, and the like.

[Memory Region R_{MC} and Peripheral Region R_{PC}]

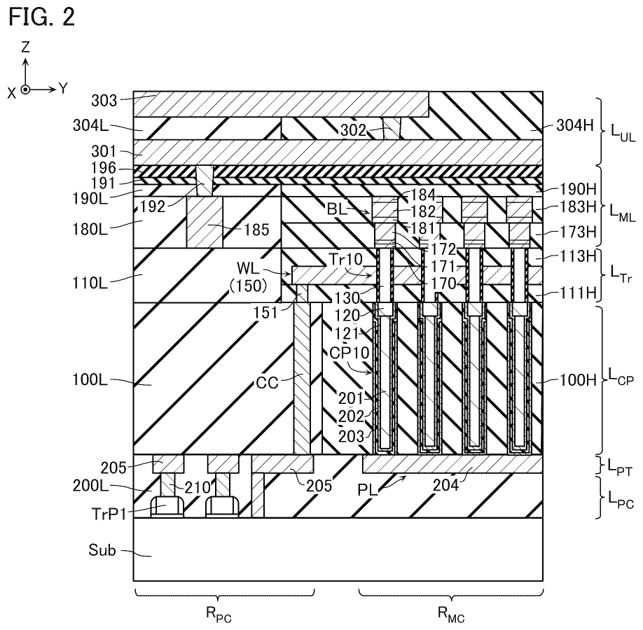

FIG. 2 is a schematic cross-sectional view illustrating a part of a configuration of the semiconductor device according to the first embodiment. As illustrated in FIG. 2, the semiconductor device according to the first embodiment includes a substrate Sub, a transistor layer L_{Tr} spaced from the substrate Sub in the Z-direction, a wiring layer L_{ML} disposed on the transistor layer L_{Tr}, a wiring layer L_{UL} disposed on the wiring layer L_{ML}, a capacitor layer L_{CP} disposed under the transistor layer L_{Tr}, a plate line layer L_{PT} disposed under the capacitor layer L_{CP}, and a peripheral circuit layer L_{PC} disposed on the substrate Sub under the plate line layer L_{PT}. The substrate Sub contains, for example, P-type silicon (Si) containing P-type impurities, such as boron (B).

As illustrated in FIG. 2, the semiconductor device according to the first embodiment includes a memory region R_{MC} and a peripheral region R_{PC} which are disposed on the substrate Sub. The memory region R_{MC} and the peripheral region R_{PC} are arranged in the Y-direction.

### [Structure of Memory Region R_{MC}]

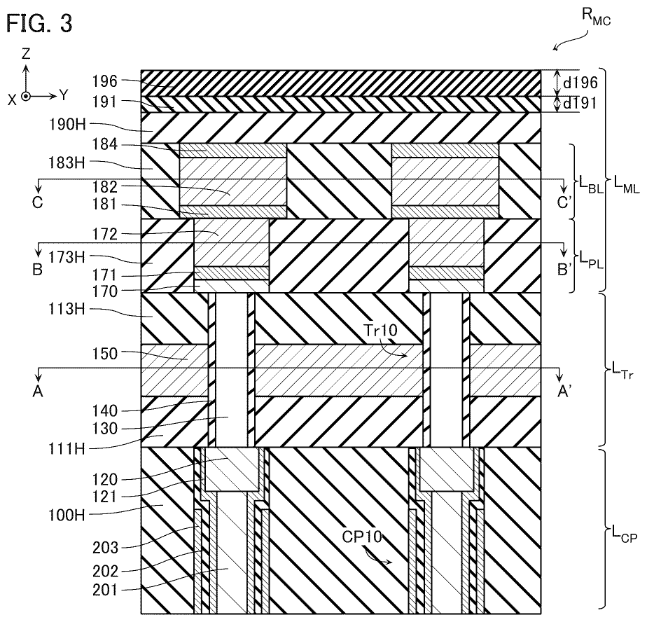

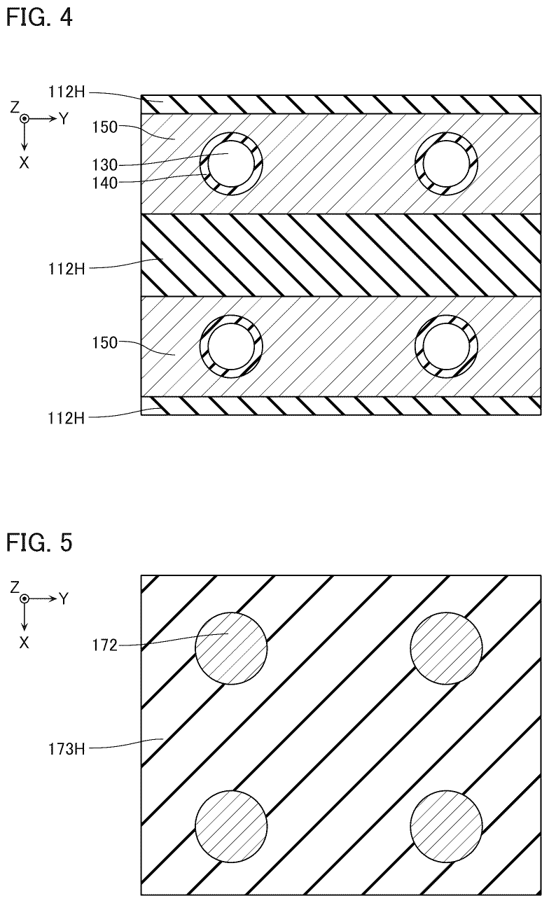

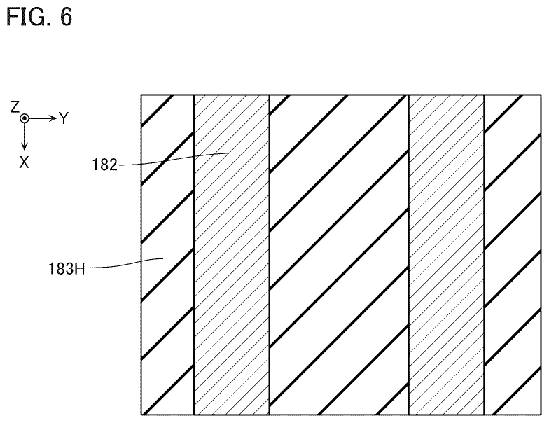

Next, with reference to FIG. 2 to FIG. 6, a structure of the memory region R_{MC} is described. FIG. 3 is a schematic cross-sectional view illustrating a part of a configuration of the memory region R_{MC}. FIG. 4 is a schematic cross-sectional view of the configuration illustrated in FIG. 3 taken along a line A-A′ and viewed in an arrow direction. FIG. 5 is a schematic cross-sectional view of the configuration illustrated in FIG. 3 taken along a line B-B′ and viewed in an arrow direction. FIG. 6 is a schematic cross-sectional view of the configuration illustrated in FIG. 3 taken along a line C-C′ and viewed in an arrow direction.

The transistor layer L_{Tr} in the memory region R_{MC} includes, for example, as illustrated in FIG. 2 to FIG. 4, an insulating layer 111H disposed on an upper surface of the capacitor layer L_{CP}, an insulating layer 113H disposed above the insulating layer 111H, a plurality of insulating layers 112H and a plurality of conductive layers 150 (FIG. 4), which are disposed between the insulating layer 111H and the insulating layer 113H and alternately arranged in the X-direction, and electrodes 151 (FIG. 2) connected to lower ends of the conductive layers 150. The insulating layer 111H, the insulating layers 112H, and the insulating layer 113H are described later.

Additionally, the transistor layer L_{Tr} in the memory region R_{MC} includes, for example, as illustrated in FIG. 4, a plurality of semiconductor layers 130, which are arranged in the Y-direction corresponding to the plurality of conductive layers 150 and arranged in the X-direction along the plurality of conductive layers 150, and a plurality of insulating layers 140 disposed on respective outer peripheral surfaces of the plurality of semiconductor layers 130. Hereinafter, a structure including a semiconductor layer 130, an insulating layer 140, and a part of a conductive layer 150 may be referred to as a transistor structure Tr10 (FIG. 2). The transistor structure Tr10 functions as the select transistor ST (FIG. 1).

The semiconductor layer 130, for example, extends in the Z-direction and has an approximately columnar shape. The semiconductor layer 130 functions as, for example, the channel region of the select transistor ST (FIG. 1). The semiconductor layer 130 includes an oxide semiconductor. For example, the semiconductor layer 130 contains at least one element selected from the group consisting of indium (In), gallium (Ga), zinc (Zn), magnesium (Mg), aluminum (Al), calcium (Ca), titanium (Ti), manganese (Mn), cadmium (Cd), and tin (Sn) and contains zinc (Zn) and oxygen (O). The semiconductor layer 130 contains, for example, indium (In), gallium (Ga), zinc (Zn), and oxygen (O).

The insulating layer 140, for example, extends in the Z-direction and has an approximately cylindrical shape. A part of the insulating layer 140 is disposed between the conductive layer 150 and the semiconductor layer 130. The insulating layer 140 functions as, for example, the gate insulating film of the select transistor ST (FIG. 1). The insulating layer 140 contains, for example, silicon oxide (SiO₂) and the like. The insulating layer 140 may be a stacked structure of silicon oxide (SiO₂) and an insulating layer of silicon nitride (SiN) or another high dielectric constant material.

The conductive layer 150, for example, extends in the Y-direction. The conductive layer 150 surrounds parts of respective outer peripheral surfaces of a plurality of semiconductor layers 130 arranged in the Y-direction and is opposed to parts of the outer peripheral surfaces of the semiconductor layers 130. The conductive layer 150 functions as the gate electrodes of a plurality of the select transistors ST arranged in the Y-direction and the word line WL of the memory cell array MCA (FIG. 1). The conductive layer 150 may contain, for example, tungsten (W) or a stacked structure of titanium nitride (TiN) and tungsten (W).

The electrode 151, for example, extends in the Z-direction and has an approximately columnar shape. The electrode 151 contains, for example, tungsten (W) or a stacked structure of titanium nitride (TiN) and tungsten (W).

For example, as illustrated in FIG. 3, the wiring layer L_{ML} in the memory region R_{MC} includes a plug layer L_{PL} disposed on an upper surface of the transistor layer L_{Tr}, a bit line layer L_{BL} disposed on an upper surface of the plug layer L_{PL}, an insulating layer 190H disposed on an upper surface of the bit line layer L_{BL}, and a metal oxide layer 191 and an insulating layer 196, which are disposed on an upper surface of the insulating layer 190H. The insulating layer 190H is described later.

For example, as illustrated in FIG. 3 and FIG. 5, the plug layer L_{PL} includes conductive layers 170, conductive layers 171, and conductive layers 172 disposed in sequence on the upper surface of the transistor layer L_{Tr} at positions corresponding to the semiconductor layers 130. The conductive layers 170, the conductive layers 171, and the conductive layers 172 are electrically connected to the semiconductor layers 130.

A structure including a conductive layer 170, a conductive layer 171, and a conductive layer 172 has, for example, as illustrated in FIG. 3 and FIG. 5, an approximately columnar shape extending in the Z-direction, and a plurality of the structures are disposed to be arranged in the X-direction and the Y-direction. The conductive layer 170, the conductive layer 171, and the conductive layer 172 function as, for example, a source electrode of the select transistor ST. Between the structures including the conductive layers 170, the conductive layers 171, and the conductive layers 172, for example, an insulating layer 173H is disposed. The insulating layer 173H is described later.

The conductive layer 170 contains, for example, at least one element selected from the group consisting of indium (In), tin (Sn), niobium (Nb), titanium (Ti), tungsten (W), ruthenium (Ru), tantalum (Ta), iridium (Ir), and molybdenum (Mo) and contains oxygen (O). The conductive layer 170 may be, for example, indium tin oxide (InSnO).

The conductive layer 171 contains, for example, titanium nitride (TiN) and the like.

The conductive layer 172 contains, for example, tungsten (W), aluminum (Al), molybdenum (Mo), and the like.

For example, as illustrated in FIG. 3 and FIG. 6, the bit line layer L_{BL} includes conductive layers 181, conductive layers 182, and conductive layers 184 disposed in sequence on an upper surface of the plug layer L_{PL} at positions corresponding to the conductive layers 172. The conductive layers 181, the conductive layers 182, and the conductive layers 184 are electrically connected to a plurality of the conductive layers 172 arranged in the X-direction.

For example, as illustrated in FIG. 3 and FIG. 6, a structure including a conductive layer 181, a conductive layer 182, and a conductive layer 184 extends in the X-direction, and a plurality of the structures are disposed to be arranged in the Y-direction. The conductive layer 181, the conductive layer 182, and the conductive layer 184 function as, for example, the bit line BL (FIG. 1) of the memory cell array MCA. Between the structures including the conductive layers 181, the conductive layers 182, and the conductive layers 184, for example, an insulating layer 183H is disposed. The insulating layer 183H is described later.

The conductive layer 181 and the conductive layer 184 contain, for example, titanium nitride (TiN) and the like.

The conductive layer 182 contains, for example, tungsten (W), aluminum (Al), molybdenum (Mo), and the like.

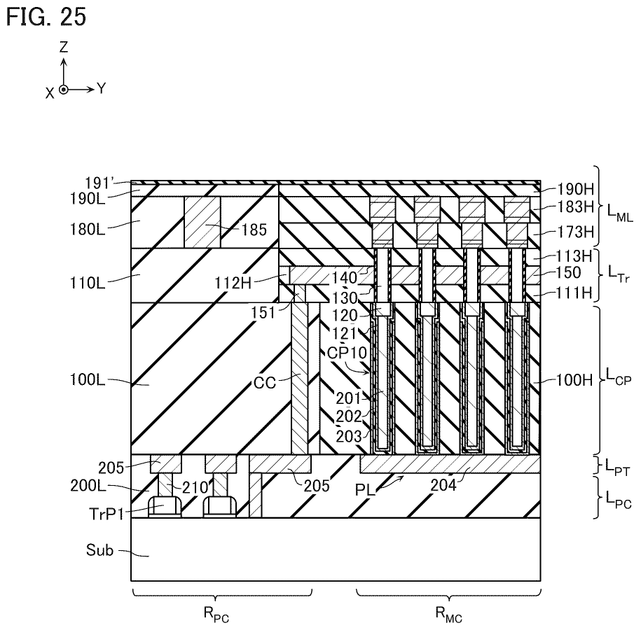

For example, as illustrated in FIG. 2, the metal oxide layer 191 and the insulating layer 196 extend in the X-direction and the Y-direction and are disposed across the memory region R_{MC} and the peripheral region R_{PC}. At least a part of the metal oxide layer 191 functions as, for example, a layer to enhance an oxygen introduction efficiency to the semiconductor layers 130 in a first oxidation process (FIG. 25) described later. Further, the metal oxide layer 191 functions as, for example, a layer to avoid diffusion of hydrogen (H) from the insulating layer 196 and to avoid reduction of the semiconductor layers 130 (occurrence of deoxygenation) in a post-annealing process described later.

The metal oxide layer 191 contains a metallic element ME and oxygen (O). The metallic element ME is, for example, at least one metallic element selected from the group consisting of aluminum (Al), hafnium (Hf), zirconium (Zr), lanthanum (La), and yttrium (Y).

The metal oxide layer 191 contains, for example, the metallic element ME and oxygen (O) as main components. The metal oxide layer 191 may contain, for example, a metal oxide, such as aluminum oxide (AlO), hafnium oxide (HfO), zirconium oxide (Zro), lanthanum oxide (LaO), and yttrium oxide (YO). When the metal oxide layer 191 contains aluminum oxide (AlO), hafnium oxide (HfO), zirconium oxide (Zro), lanthanum oxide (LaO), or yttrium oxide (YO), the insulating property of the metal oxide layer 191 improves.

The metal oxide layer 191 has a film thickness d191 (FIG. 3) in the Z-direction. The film thickness d191 is, for example, 5 nm or more and 20 nm or less. The metal oxide layer 191 is formed in the film thickness, thereby avoiding the reduction of the semiconductor layers 130 (occurrence of deoxygenation) in the post-annealing process described later more effectively.

The insulating layer 196 is disposed, for example, on an upper surface of the metal oxide layer 191 to be in contact with the metal oxide layer 191. The insulating layer 196 contains, for example, nitrogen (N) and silicon (Si). The insulating layer 196 may be silicon nitride (Si₃N₄). The insulating layer 196 contains a large amount of hydrogen (H) in the material in some cases and becomes a supply source of hydrogen in some cases. For example, in the post-annealing process described later, hydrogen (H) detaches from the insulating layer 196 and diffuses to surrounding regions in some cases. The insulating layer 196 has a film thickness d196 (FIG. 3) in the Z-direction. The film thickness d196 is, for example, 5 nm or more and 100 nm or less.

For example, as illustrated in FIG. 2, the wiring layer L_{UL} in the memory region R_{MC} includes a wiring 301 disposed on an upper surface of the insulating layer 196, a wiring 302 disposed on an upper surface of the wiring 301 to be connected to the wiring 301, and a wiring 303 disposed on an upper surface of the wiring 302 to be connected to the wiring 302. Between the wiring 301, the wiring 302, and the wiring 303, an insulating layer 304H is disposed. The insulating layer 304H is described later.

The wiring 301, the wiring 302, and the wiring 303 function as, for example, wirings for applying a voltage and a current to the bit lines BL. The wiring 301, the wiring 302, and the wiring 303 contain, for example, copper (Cu), tungsten (W), aluminum (Al), and the like.

The capacitor layer L_{CP} in the memory region R_{MC} includes, for example, as illustrated in FIG. 2 and FIG. 3, a plurality of capacitor structures CP10 arranged in the X-direction and the Y-direction. The plurality of capacitor structures CP10 are disposed corresponding to the respective plurality of transistor structures Tr10.

The capacitor structure CP10 includes a conductive layer 120 connected to a lower end of the semiconductor layer 130, a conductive layer 201 connected to a lower end of the conductive layer 120, a conductive layer 121 disposed on an outer peripheral surface of the conductive layer 120 and on an outer peripheral surface and a lower surface of the conductive layer 201, an insulating layer 202 disposed on an outer peripheral surface and a lower surface of the conductive layer 121, and a conductive layer 203 disposed on an outer peripheral surface and a lower surface of the insulating layer 202. The capacitor structure CP10 functions as the capacitor Cap (FIG. 1). Between the plurality of capacitor structures CP10, for example, an insulating layer 100H is disposed. The insulating layer 100H is described later.

The conductive layer 120 functions as, for example, a drain electrode of the select transistor ST (FIG. 1) and a part of one electrode of the capacitor Cap (FIG. 1). The conductive layer 120 has an approximately circular shape on an XY cross-sectional surface and may have a plug shape. The conductive layer 120 contains, for example, a material similar to that of the conductive layer 170. The conductive layer 120 may be, for example, indium tin oxide (InSnO).

The conductive layer 121 functions as, for example, a part of the one electrode of the capacitor Cap (FIG. 1). The conductive layer 121 may be, for example, titanium nitride (TiN).

The conductive layer 201 functions as a part of the one electrode of the capacitor Cap (FIG. 1). The conductive layer 201 includes, for example, a stacked structure of titanium nitride (TiN) and tungsten (W).

The insulating layer 202 functions as an insulating layer between the electrodes of the capacitor Cap (FIG. 1). The insulating layer 202 contains, for example, aluminum oxide (AlO) and the like. The insulating layer 202 may be, for example, silicon oxide (SiO₂) or another insulating metal oxide.

The conductive layer 203 functions as, for example, the other electrode of the capacitor Cap (FIG. 1). The conductive layer 203 includes, for example, a stacked structure of titanium nitride (TiN) and tungsten (W).

For example, as illustrated in FIG. 2, the plate line layer L_{PT} in the memory region R_{MC} includes a conductive layer 204 disposed on a lower surface of the capacitor layer L_{CP}. The conductive layer 204 is electrically connected to a plurality of the conductive layers 203. The conductive layer 204 functions as, for example, the plate line PL (FIG. 1). The conductive layer 204 may contain, for example, tungsten (W) or a stacked structure of titanium nitride (TiN) and tungsten (W).

### [Structure of Peripheral Region R_{PC}]

Next, with reference to FIG. 2, a structure of the peripheral region R_{PC} is described.

The transistor layer L_{Tr} in the peripheral region R_{PC} includes, for example, as illustrated in FIG. 2, an insulating layer 110L in contact with the upper surface of the capacitor layer L_{CP} and a lower surface of the wiring layer L_{ML}. The insulating layer 110L is described later.

For example, as illustrated in FIG. 2, the wiring layer L_{ML} in the peripheral region R_{PC} includes an insulating layer 180L disposed on the upper surface of the transistor layer L_{Tr}, a wiring 185 disposed inside the insulating layer 180L, an electrode 192 connected to an upper surface of the wiring 185, an insulating layer 190L disposed on an upper surface of the insulating layer 180L, and the metal oxide layer 191 and the insulating layer 196, which are disposed on an upper surface of the insulating layer 190L. The insulating layer 180L and the insulating layer 190L are described later.

The wiring 185 contains, for example, copper (Cu), tungsten (W), aluminum (Al), and the like.

For example, as illustrated in FIG. 2, the electrode 192 extends in the Z-direction and has an approximately columnar shape. The electrode 192 has an upper surface disposed at, for example, the same position as the upper surface of the insulating layer 196. The electrode 192 is disposed, for example, to penetrate the insulating layer 190L, the metal oxide layer 191, and the insulating layer 196. The electrode 192 may contain, for example, tungsten (W) or a stacked structure of titanium nitride (TiN) and tungsten (W).

For example, as illustrated in FIG. 2, the wiring layer L_{UL} in the peripheral region R_{PC} basically has a structure similar to that of the wiring layer L_{UL} in the memory region R_{MC}. However, in the wiring layer L_{UL} in the peripheral region R_{PC}, instead of the insulating layer 304H, an insulating layer 304L is disposed between the wiring 301, the wiring 302, and the wiring 303. The insulating layer 304L is described later.

For example, as illustrated in FIG. 2, the capacitor layer L_{CP} in the peripheral region R_{PC} includes an insulating layer 100L disposed on an upper surface of the plate line layer L_{PT} and electrodes CC disposed to penetrate the insulating layer 100L. The insulating layer 100L is described later.

For example, the electrodes CC extend in the Z-direction, have upper ends electrically connected to the electrodes 151 and lower ends electrically connected to parts of a plurality of conductive layers 205 (described later) in the plate line layer L_{PT}. The electrodes CC may contain, for example, tungsten (W) or a stacked structure of titanium nitride (TiN) and tungsten (W).

For example, as illustrated in FIG. 2, the plate line layer L_{PT} in the peripheral region R_{PC} includes the plurality of conductive layers 205 disposed on the lower surface of the capacitor layer L_{CP}. The conductive layers 205 may contain, for example, a material similar to that of the conductive layer 204.

For example, as illustrated in FIG. 2, the peripheral circuit layer L_{PC} in the peripheral region R_{PC} includes a plurality of peripheral transistors TrP1 disposed on the substrate Sub and a plurality of electrodes 210 connected to the plurality of peripheral transistors TrP1.

The peripheral transistor TrP1 has a part of the substrate Sub as a channel region. The plurality of peripheral transistors TrP1 constitute, for example, at least a part of the peripheral circuit PC (FIG. 1).

For example, the electrodes 210 have upper ends connected to the conductive layers 205. For example, the electrodes 210 have lower ends connected to source regions, drain regions, gate electrodes, and the like of the plurality of peripheral transistors TrP1. The electrodes 210 may contain, for example, copper (Cu), tungsten (W), or a stacked structure of titanium nitride (TiN) and tungsten (W).

Between the plurality of peripheral transistors TrP1, the plurality of electrodes 210, and the plurality of conductive layers 205, an insulating layer 200L is disposed. The insulating layer 200L is described later.

[Insulating Layers in Memory Region R_{MC} and Peripheral Region R_{PC}]

The insulating layer 100H, the insulating layer 111H, the insulating layers 112H (FIG. 4), the insulating layer 113H, the insulating layer 173H, the insulating layer 183H, the insulating layer 190H, and the insulating layer 304H may be referred to as insulating layers belonging to an insulating layer group H or simply as the insulating layer group H below. In the layers other than the peripheral circuit layer L_{PC} in the memory region R_{MC}, the insulating layers belonging to the insulating layer group H are formed, as illustrated in FIG. 2 and FIG. 3.

The insulating layer group H contains a material with which the diffusion of hydrogen (H) is less likely to occur. The insulating layer group H contains, for example, a material with a relatively high density. In the insulating layer group H, for example, a film with high crystallinity is contained, and the diffusion of hydrogen (H) through grain boundaries or highly amorphous portions is less likely to occur. Hydrogen (H) is difficult to pass through the insulating layer group H.

The insulating layer group H contains, for example, silicon (Si) and oxygen (O). The insulating layer group H contains, for example, silicon oxide (SiO₂) and the like with a relatively high density.

The insulating layer group H is formed by, for example, Chemical Vapor Deposition (CVD). When the insulating layer group H is formed by CVD, it is formed under a relatively high temperature, for example, at a stage temperature of about 400° C. Hereinafter, a case where the insulating layer group H is formed by CVD may be referred to as high-temperature CVD.

The insulating layer group H, for example, avoids hydrogen (H) and the like, which detach from the insulating layer 196, diffusing through the insulating layer group H and reaching the semiconductor layers 130 in the post-annealing process described later.

The insulating layer 200L, the insulating layer 100L, the insulating layer 110L, the insulating layer 180L, the insulating layer 190L, and the insulating layer 304L may be referred to as insulating layers belonging to an insulating layer group L or simply as the insulating layer group L below. In the peripheral circuit layer L_{PC} in the peripheral region Rec and the memory region R_{MC}, an insulating layer belonging to the insulating layer group L is formed, as illustrated in FIG. 2.

The insulating layer group L contains a material with which the diffusion of hydrogen (H) is likely to occur. The insulating layer group L contains, for example, a material with a relatively low density. In the insulating layer group L, for example, a film with low crystallinity is contained, and the diffusion of hydrogen (H) through grain boundaries or highly amorphous portions is likely to occur. Hydrogen (H) is easy to pass through the insulating layer group L.

The insulating layer group L contains, for example, silicon (Si) and oxygen (O). The insulating layer group L contains, for example, silicon oxide (SiO₂) and the like with a relatively low density.

The insulating layer group L is formed by, for example, CVD. When the insulating layer group L is formed by CVD, it is formed under a relatively low temperature, for example, at a stage temperature of about 300° C. Hereinafter, a case where the insulating layer group L is formed by CVD may be referred to as low-temperature CVD.

The insulating layer group L, for example, makes it easy for hydrogen (H) and the like, which detach from the insulating layer 196, to diffuse through the insulating layer group L and reach the peripheral transistors TrP1 in the post-annealing process described later.

A density of the insulating layer group H is greater than a density of the insulating layer group L. For example, the average density of a plurality of materials constituting the insulating layer group H is greater than the average density of a plurality of materials constituting the insulating layer group L. The densities of the materials contained in the insulating layer group H and the insulating layer group L can be measured by, for example, Electron Energy Loss Spectroscopy, X-Ray Reflectivity, or the like.

The insulating layer group H and the insulating layer group L may contain, for example, hydrogen (H). When the insulating layer group H and the insulating layer group L contain hydrogen (H), a hydrogen concentration of the insulating layer group H is lower than a hydrogen concentration of the insulating layer group L. For example, the average hydrogen concentration of the plurality of materials constituting the insulating layer group H is lower than the average hydrogen concentration of the plurality of materials constituting the insulating layer group L. The hydrogen (H) concentrations of the insulating layer group H and the insulating layer group L can be measured by, for example, Secondary Ion Mass Spectrometry (SIMS) or the like.

### Manufacturing Method of First Embodiment

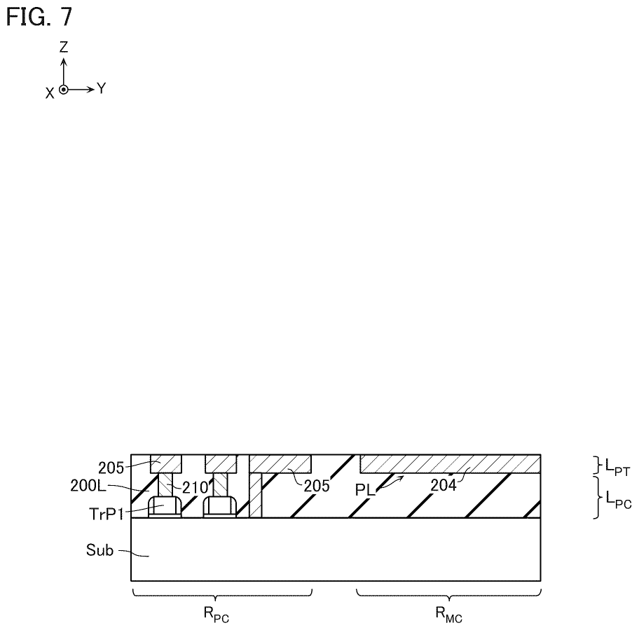

Next, with reference to FIG. 7 to FIG. 27, a method of manufacturing the semiconductor device according to this embodiment is described. FIG. 7 to FIG. 27 are schematic cross-sectional views for describing the method of manufacturing the semiconductor device according to the first embodiment. Hereinafter, the drawings according to the manufacturing method are schematic, and for convenience of explanation, a part of a configuration and the like is omitted in some cases.

In the manufacturing method, for example, as illustrated in FIG. 7, the peripheral circuit layer L_{PC} (FIG. 2) including the peripheral transistors TrP1 is formed on the substrate Sub, and next, the plate line layer L_{PT} (FIG. 2) is formed. In this process, for example, the peripheral transistors TrP1 are formed on a surface of the substrate Sub, and electrodes, wiring, and the like are formed. The peripheral transistors TrP1 include, for example, isolation dielectrics and wells (not illustrated), gate insulating films, gate electrodes, sources and drains (not illustrated), and the like.

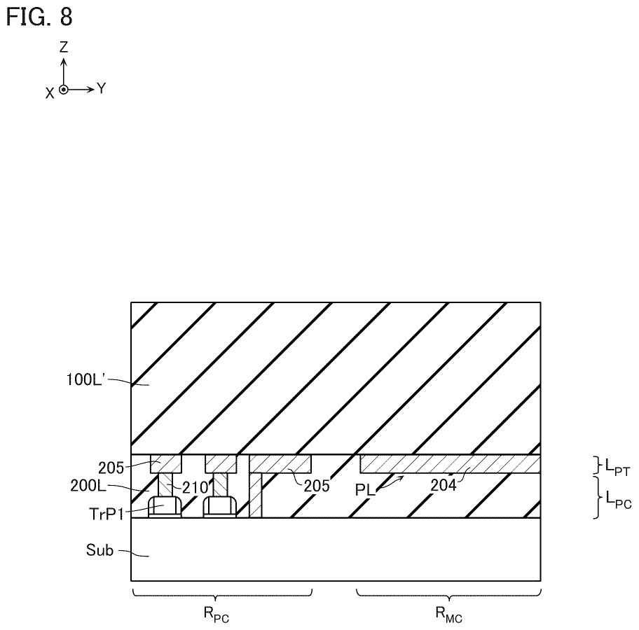

Next, for example, as illustrated in FIG. 8, an insulating layer 100L′ is formed on the upper surface of the plate line layer L_{PT}. The insulating layer 100L′ contains, for example, a material similar to that of the insulating layer 100L. This process is performed by, for example, the above-described low-temperature CVD or the like.

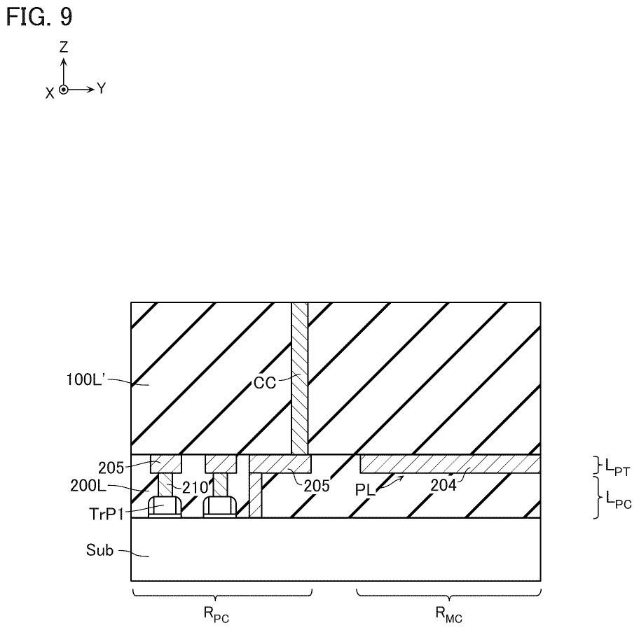

Next, for example, as illustrated in FIG. 9, openings are formed at positions corresponding to the electrodes CC. A material similar to that of the electrodes CC is used to form films in the openings, and an unnecessary material formed on an upper surface of the insulating layer 100L′ is removed to form the electrodes CC. This process is performed by, for example, Reactive Ion Etching (RIE), CVD, and Chemical Mechanical Planarization (CMP) or the like.

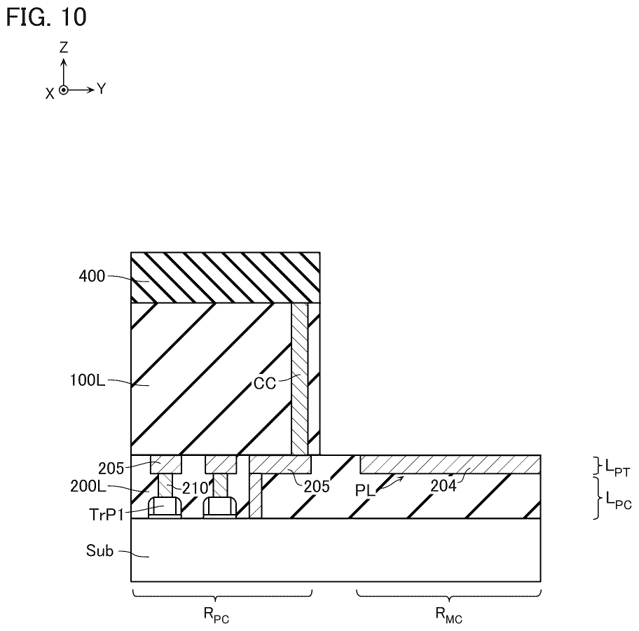

Next, for example, as illustrated in FIG. 10, a mask material 400 is formed at a position corresponding to the peripheral region R_{PC} of the capacitor layer L_{CP} by photolithography or the like, and a part of the insulating layer 100L′ not coated with the mask material 400 is removed to form the insulating layer 100L. This process is performed by, for example, RIE, wet etching, or the like.

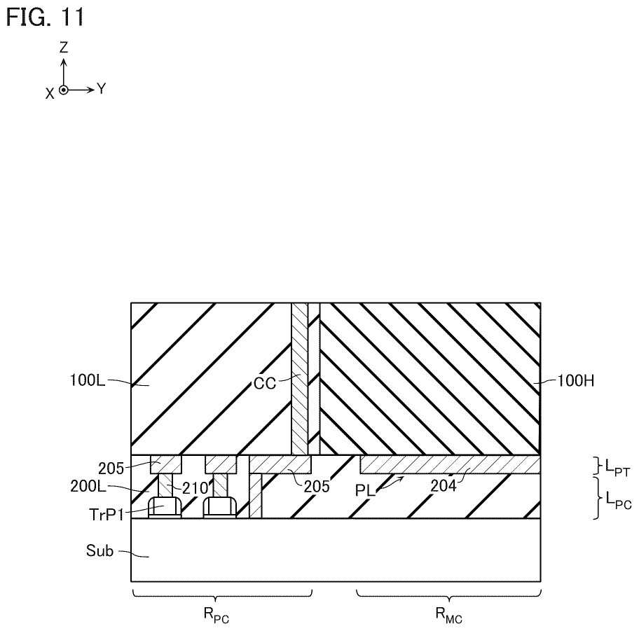

Next, for example, as illustrated in FIG. 11, a material similar to that of the insulating layer 100H is formed at a position corresponding to the memory region R_{MC} of the capacitor layer L_{CP}, and an unnecessary material formed on an upper surface of the insulating layer 100L is removed to form the insulating layer 100H. This process is performed by, for example, the above-described high-temperature CVD and CMP or the like.

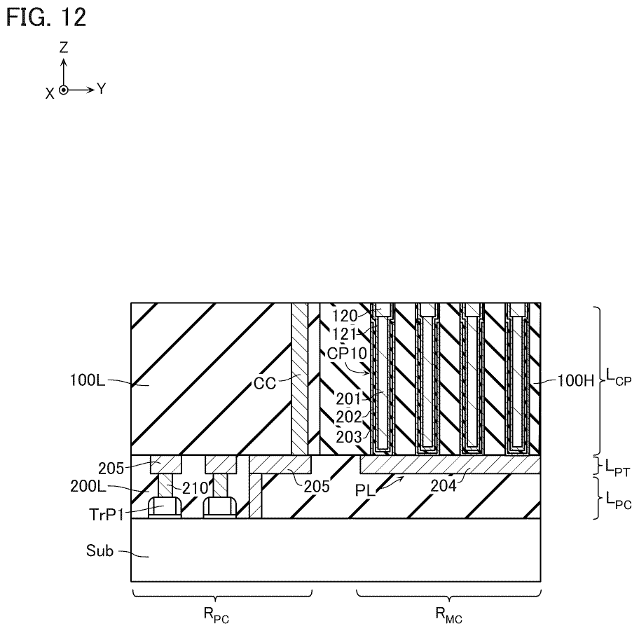

Next, for example, as illustrated in FIG. 12, the capacitor structures CP10 are formed in the memory region R_{MC}. The capacitor structures CP10 are formed by forming openings at positions corresponding to the capacitor structures CP10 and forming the conductive layer 203, the insulating layer 202, the conductive layer 121, the conductive layer 201, and the conductive layer 120 in sequence in the openings. This process is performed by, for example, RIE, CVD, and CMP or the like.

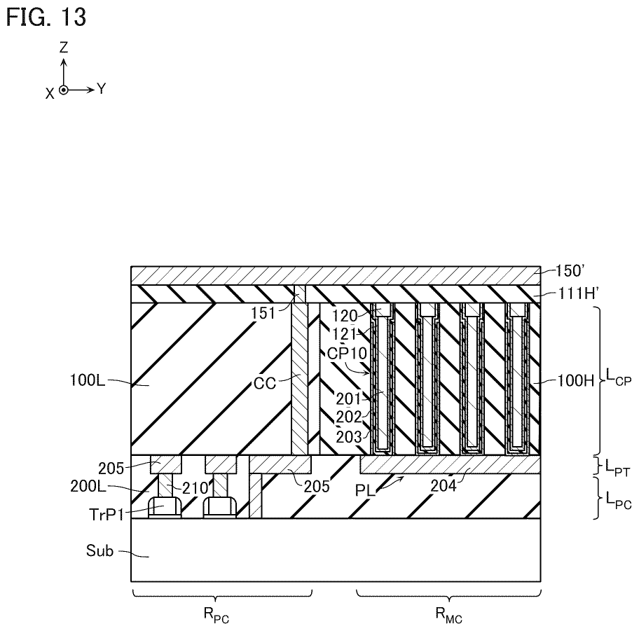

Next, for example, as illustrated in FIG. 13, an insulating layer 111H′ containing a material similar to that of the insulating layer 111H is formed on the upper surface of the capacitor layer L_{CP}. This process is performed by, for example, the above-described high-temperature CVD. In addition, the electrodes 151 are formed inside the insulating layer 111H′, and conductive layers 150′ containing a material similar to that of the conductive layers 150 are formed on upper surfaces of the insulating layer 111H′ and the electrodes 151. This process is performed by, for example, RIE, CVD, and CMP or the like.

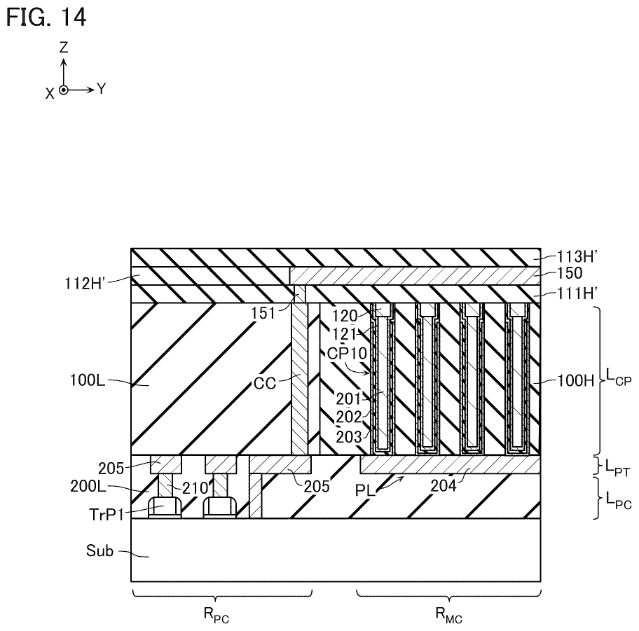

Next, for example, as illustrated in FIG. 14, the conductive layers 150 are formed. This process is performed by, for example, photolithography and RIE or the like. Further, insulating layers 112H′ containing a material similar to that of the insulating layers 112H are formed between the plurality of conductive layers 150, and an insulating layer 113H′ containing a material similar to that of the insulating layer 113H is formed on upper surfaces of the conductive layers 150 and the insulating layers 112H′. This process is performed by, for example, the above-described high-temperature CVD and CMP or the like.

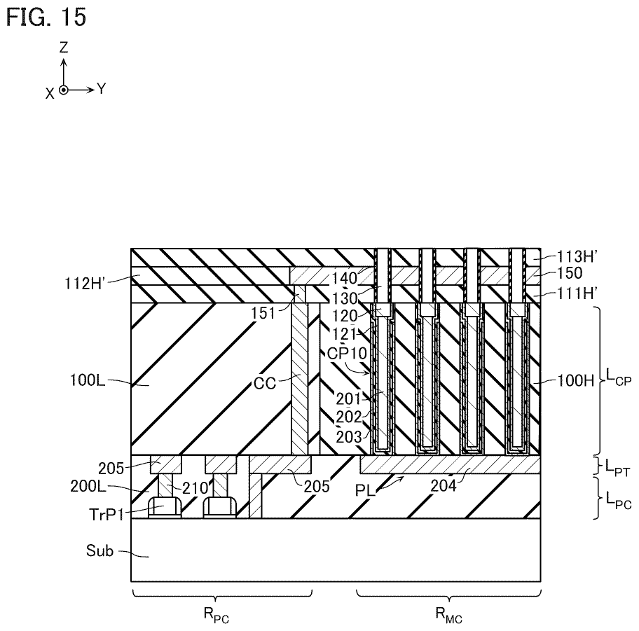

Next, for example, as illustrated in FIG. 15, openings are formed at positions corresponding to the insulating layers 140 and the semiconductor layers 130. Materials similar to those of the insulating layers 140 and the semiconductor layers 130 are formed on opening inner side surfaces and in the openings, respectively, and unnecessary materials formed on an upper surface of the insulating layer 113H′ are removed to form the insulating layers 140 and the semiconductor layers 130. This process is performed by RIE, CVD, CMP, and the like.

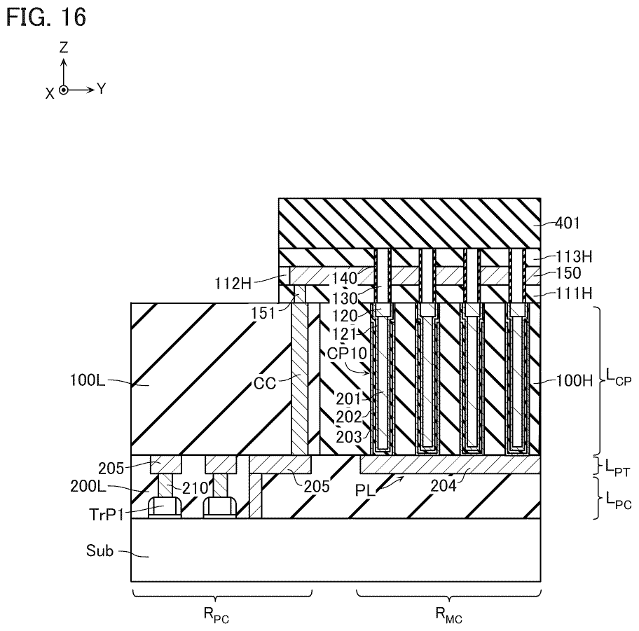

Next, for example, as illustrated in FIG. 16, a mask material 401 is formed at a position corresponding to the memory region R_{MC} of the transistor layer L_{Tr} by photolithography or the like, and parts of the insulating layer 111H′, the insulating layers 112H′, and the insulating layer 113H′ not coated with the mask material 401 are removed to form the insulating layer 111H, the insulating layers 112H, and the insulating layer 113H. This process is performed by, for example, RIE or wet etching and the like.

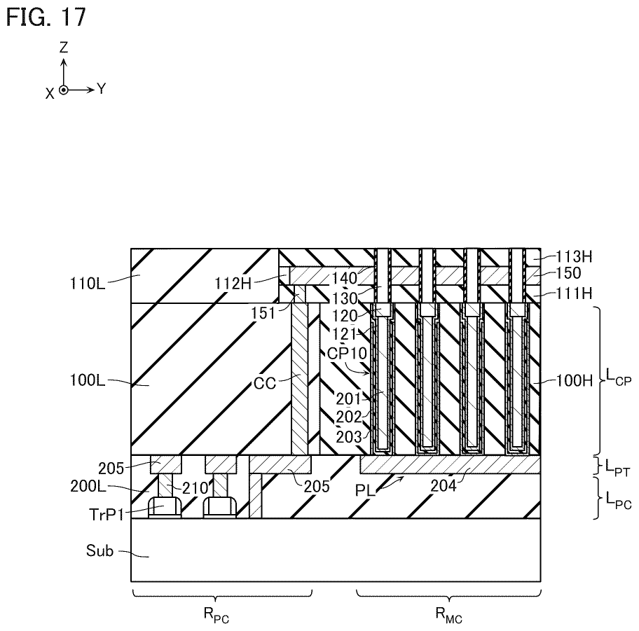

Next, for example, as illustrated in FIG. 17, an insulating layer containing a material similar to that of the insulating layer 110L is formed at a position corresponding to the peripheral region R_{PC} of the transistor layer L_{Tr}, and an unnecessary material formed on an upper surface of the insulating layer 113H is removed to form the insulating layer 110L. This process is performed by, for example, the above-described low-temperature CVD, CMP, and the like.

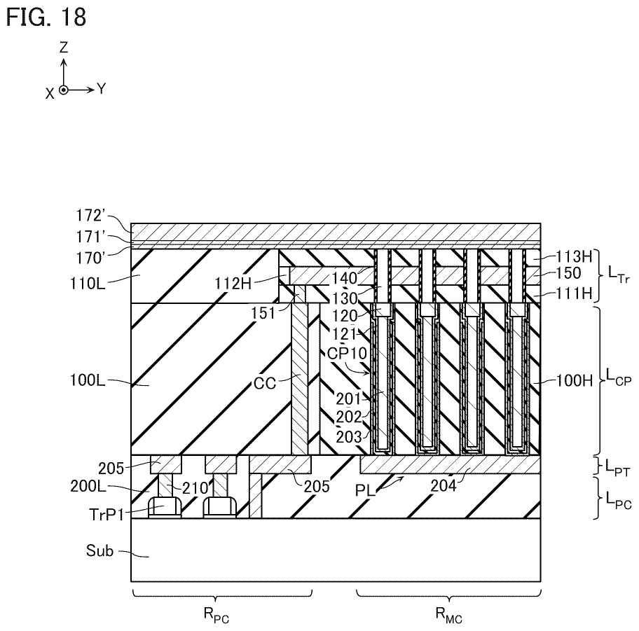

Next, for example, as illustrated in FIG. 18, a conductive layer 170′, a conductive layer 171′, and a conductive layer 172′ containing materials similar to those of the conductive layers 170, the conductive layers 171, and the conductive layers 172 are formed in sequence on the upper surface of the transistor layer L_{Tr}. This process is performed by, for example, CVD or the like.

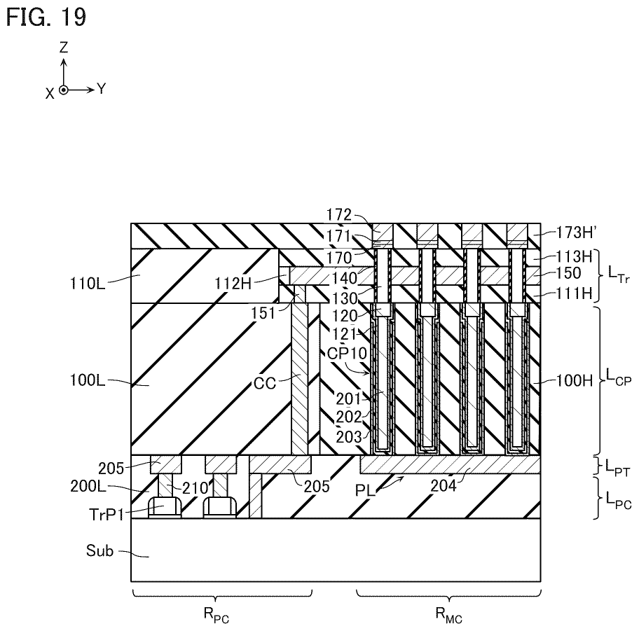

Next, for example, as illustrated in FIG. 19, a mask material is formed by photolithography or the like, and a part not coated with the mask material is removed to form the conductive layers 170, the conductive layers 171, and the conductive layers 172. This process is performed by, for example, RIE or the like. In addition, an insulating layer containing a material similar to that of the insulating layer 173H is formed between the plurality of conductive layers 170, the conductive layers 171, and the conductive layers 172, and an unnecessary material formed on the conductive layers 172 is removed to form an insulating layer 173H′. This process is performed by, for example, the above-described high-temperature CVD, CMP, and the like.

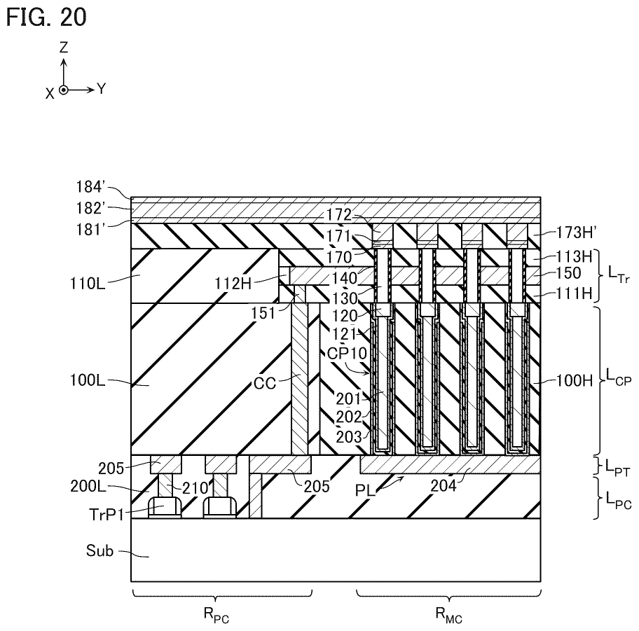

Next, for example, as illustrated in FIG. 20, a conductive layer 181′, a conductive layer 182′, and a conductive layer 184′ containing materials similar to those of the conductive layers 181, the conductive layers 182, and the conductive layers 184 are formed in sequence on upper surfaces of the insulating layer 173H′ and the conductive layers 172. This process is performed by, for example, CVD or the like.

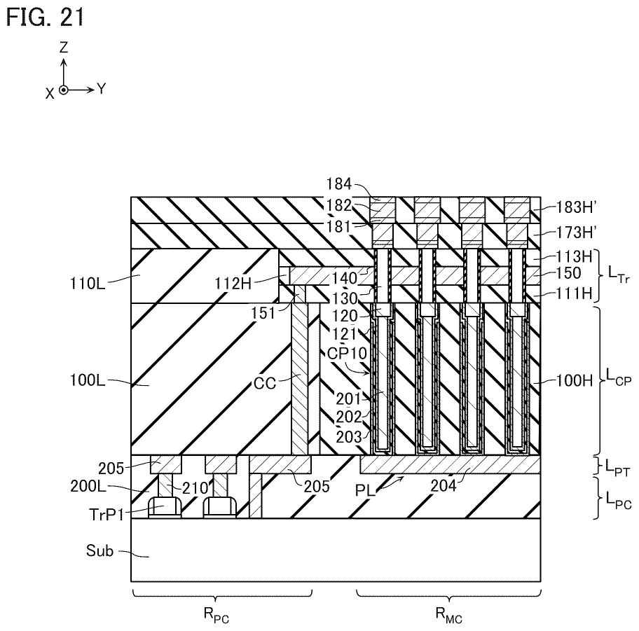

Next, for example, as illustrated in FIG. 21, a mask material is formed by photolithography or the like, and a part not coated with the mask material is removed to form the conductive layers 181, the conductive layers 182, and the conductive layers 184. This process is performed by, for example, RIE or the like. In addition, an insulating layer containing a material similar to that of the insulating layer 183H is formed between the plurality of conductive layers 181, the conductive layers 182, and the conductive layers 184, and an unnecessary material formed on the upper surfaces of the conductive layers 184 is removed to form an insulating layer 183H′. This process is performed by, for example, the above-described high-temperature CVD, CMP, and the like.

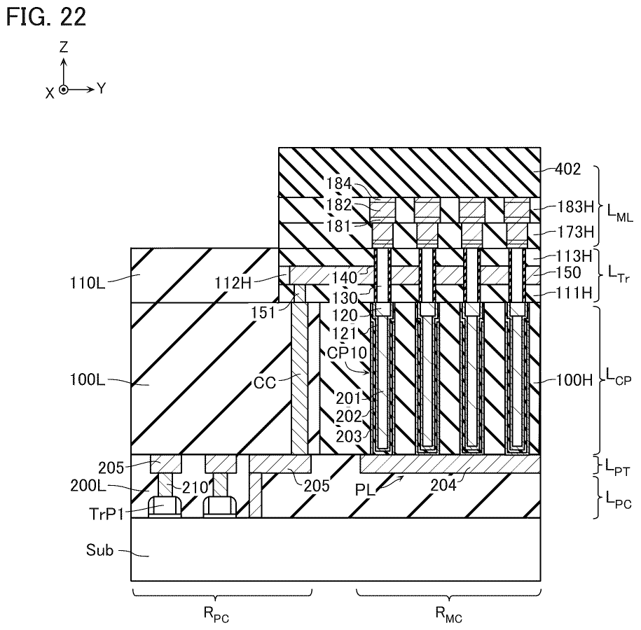

Next, for example, as illustrated in FIG. 22, a mask material 402 is formed at a position corresponding to the memory region R_{MC} of the wiring layer L_{ML} by photolithography or the like, and parts of the insulating layer 173H′ and the insulating layer 183H′ not coated with the mask material 402 are removed to form the insulating layer 173H and the insulating layer 183H. This process is performed by, for example, RIE or wet etching and the like.

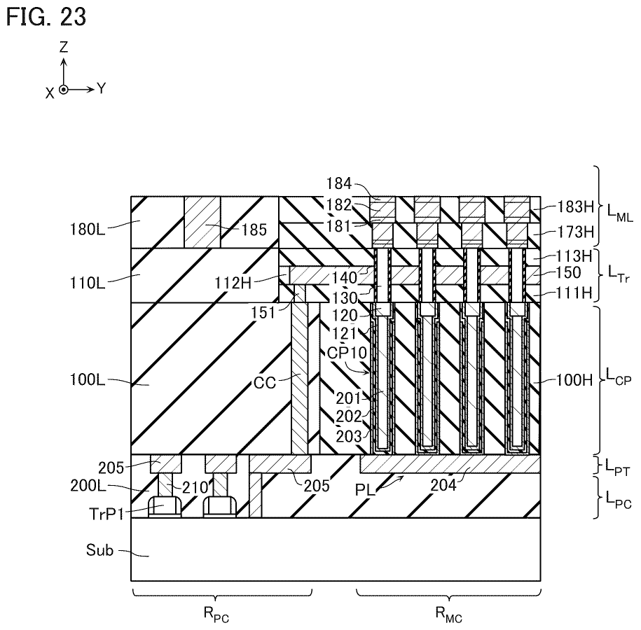

Next, for example, as illustrated in FIG. 23, an insulating layer containing a material similar to that of the insulating layer 180L is formed at a part of a position corresponding to the peripheral region R_{PC} of the wiring layer L_{ML}, and an unnecessary material formed on upper surfaces of the insulating layer 183H and the conductive layers 184 are removed to form the insulating layer 180L. This process is performed by, for example, the above-described low-temperature CVD, CMP, and the like. In addition, a part of the insulating layer 180L is removed to form the wiring 185. This process is performed by, for example, RIE, CVD, CMP, or the like.

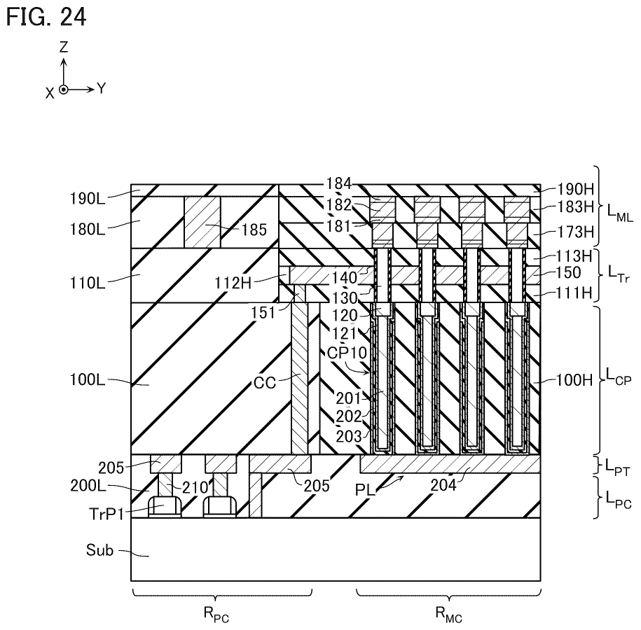

Next, for example, as illustrated in FIG. 24, the insulating layer 190H is formed on the upper surfaces of the insulating layer 183H and the conductive layers 184, and the insulating layer 190L is formed on upper surfaces of the insulating layer 180L and the wiring 185. In this process, first, an insulating layer containing a material similar to that of the insulating layer 190H is formed on upper surfaces of the structures illustrated in FIG. 23, and an unnecessary insulating layer formed in the peripheral region R_{PC} is removed. Next, an insulating layer containing a material similar to that of the insulating layer 190L is formed, and the insulating layer formed in the memory region R_{MC} is removed. The process of forming the insulating layer 190L is performed by, for example, the above-described low-temperature CVD, and RIE or wet etching. The process of forming the insulating layer 190H is performed by, for example, the above-described high-temperature CVD, and RIE or wet etching.

Next, for example, as illustrated in FIG. 25, a metal oxide layer 191′ containing a material similar to that of the metal oxide layer 191 is formed on the upper surfaces of the insulating layer 190L and the insulating layer 190H. The metal oxide layer 191′ may be, for example, 1 nm or more and 5 nm or less in a film thickness direction. This process is performed by, for example, Atomic Layer Deposition (ALD), CVD, or the like.

Next, in a state where the metal oxide layer 191′ is exposed, a first oxidation process described later is performed to introduce oxygen to the semiconductor layers 130 through, for example, the insulating layer 190H, the insulating layer 183H, the insulating layer 173H, the insulating layer 113H, the insulating layers 112H, the insulating layer 111H, and the like. When it is not necessary to enhance the oxygen introduction efficiency to the semiconductor layers 130, the formation of the metal oxide layer 191′ and the first oxidation process may be omitted.

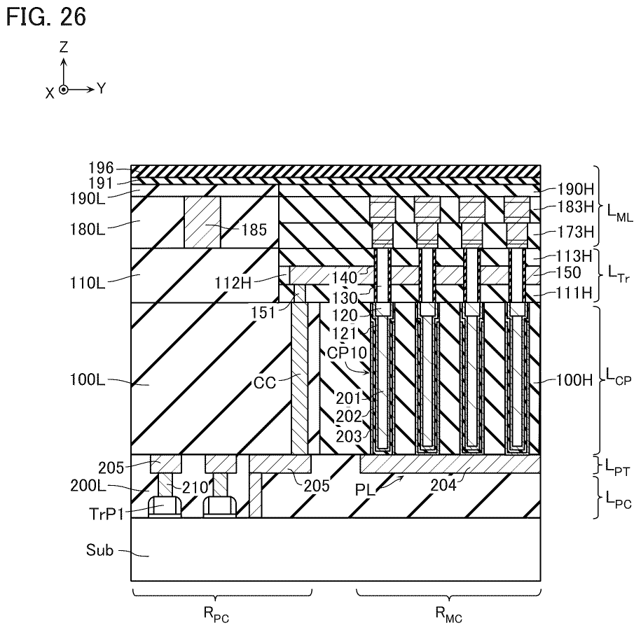

Next, for example, as illustrated in FIG. 26, the similar material is accumulated on an upper surface of the metal oxide layer 191′ to form the metal oxide layer 191, and the insulating layer 196 is then formed. This process is performed by, for example, ALD, Physical Vapor Deposition (PVD), CVD, or the like.

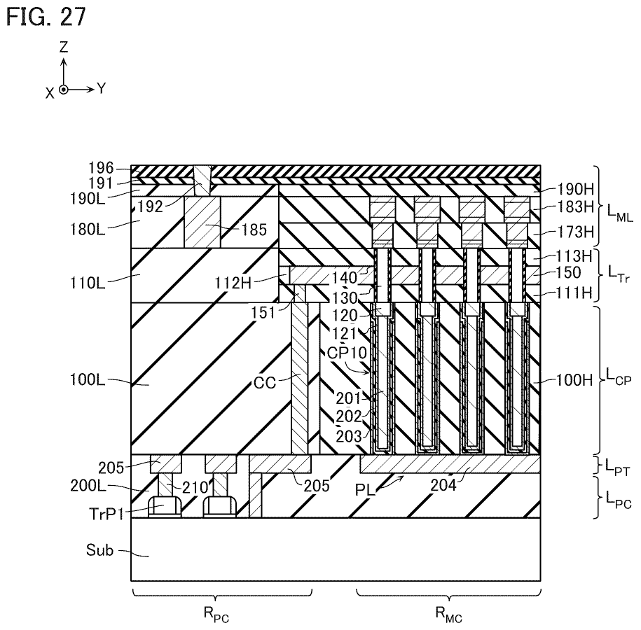

Next, for example, as illustrated in FIG. 27, an opening is formed at a position corresponding to the electrode 192. A material similar to that of the electrode 192 is used to form a film in the opening, and an unnecessary material formed on an upper surface of the insulating layer 196 is removed to form the electrode 192. This process is performed by RIE, CVD, and CMP or the like.

Next, the wiring layer L_{UL} (FIG. 2) is formed on upper surfaces of the structures illustrated in FIG. 27. In the formation of the wiring layer L_{UL} (FIG. 2), as inter-wiring layer films, the insulating layer 304H and the insulating layer 304L are formed in the memory region R_{MC} and the peripheral region R_{PC}, respectively, similarly to the process described with reference to FIG. 24.

During the formation or after the formation of the wiring layer L_{UL}, the post-annealing process described later is performed. The semiconductor device according to the first embodiment is manufactured as described above.

### [First Oxidation Process]

The first oxidation process (FIG. 25) is, for example, radical oxidation.

The radical oxidation is performed in an atmosphere containing oxygen radical or hydroxyl radical. The radical oxidation is performed in an atmosphere, for example, in which an oxygen gas (O₂), a hydrogen gas (H₂), and an argon gas (Ar) are turned into plasma. The radical oxidation is performed in an atmosphere, for example, in which water vapor is turned into plasma.

A method of generating the oxygen radical and the hydroxyl radical used for the radical oxidation is not specifically limited. The oxygen radical and the hydroxyl radical are generated, for example, using an inductively coupled plasma method, a microwave plasma method, an electron cyclotron resonance method, a helicon wave method, or a hot filament method.

The atmosphere of the radical oxidation contains, for example, hydrogen (H) and oxygen (O). An atomic ratio (H/(H+O)) of the hydrogen (H) to a sum of the hydrogen (H) and the oxygen (O) contained in the atmosphere of the radical oxidation is, for example, 40% or less. The atomic ratio (H/(H+O)) of the hydrogen (H) to the sum of the hydrogen (H) and the oxygen (O) contained in the atmosphere of the radical oxidation is, for example, 2% or more and 5% or less.

The atomic ratio (H/(H+O)) of the hydrogen (H) to the sum of the hydrogen (H) and the oxygen (O) contained in the atmosphere of the radical oxidation is adjusted, for example, using flow rates of a hydrogen gas (H₂) and an oxygen gas (O₂) introduced in the atmosphere of the radical oxidation. A mole ratio (H₂/(H₂+O₂)) of the hydrogen gas (H₂) to a sum of the hydrogen gas (H₂) and the oxygen gas (O₂) introduced in the atmosphere of the radical oxidation is, for example, 40% or less. The mole ratio (H₂/(H₂+O₂)) of the hydrogen gas (H₂) to the sum of the hydrogen gas (H₂) and the oxygen gas (O₂) introduced in the atmosphere of the radical oxidation is, for example, 2% or more and 5% or less.

A temperature of the radical oxidation is, for example, 300° C. or more and 900° C. or less. A pressure of the radical oxidation is, for example, 50 Pa or more and 3000 Pa or less.

When the first oxidation process (FIG. 25) is performed by the radical oxidation, the metal oxide layer 191′ preferably contains at least one element selected from the group consisting of nitrogen (N), carbon (C), hydrogen (H), and chlorine (Cl). When the metal oxide layer 191′ contains the above-described element, crystallization of the metal oxide layer 191′ is reduced, and oxygen introduction speed increases.

When the first oxidation process (FIG. 25) is performed by the radical oxidation, the atmosphere of the radical oxidation contains hydrogen (H) and oxygen (O), and the atomic ratio (H/(H+O)) of the contained hydrogen (H) to the sum of the hydrogen (H) and the oxygen (O) is preferably 40% or less, more preferably 2% or more and 5% or less. When the atomic ratio (H/(H+O)) meets the above-described range, the oxygen introduction speed increases.

While the case where, for example, the radical oxidation is performed as the first oxidation process is described above, the method of the first oxidation process can be adjusted as appropriate.

For example, as the first oxidation process (FIG. 25), plasma CVD or the like may be used to form a film containing oxygen (O) on the upper surface of the metal oxide layer 191′. The plasma CVD is a film forming method performed in, for example, an atmosphere in which an oxygen gas, a hydrogen gas, an argon gas, and the like are turned into plasma. The film containing oxygen (O) is, for example, silicon oxide (SiO₂) or the like.

Further, for example, as the first oxidation process (FIG. 25), oxygen plasma ashing may be performed. The oxygen plasma ashing is a process in which, for example, the metal oxide layer 191′ is irradiated with oxygen plasma in a high energy state.

### [Post-Annealing Process]

The post-annealing process is an annealing process performed, for example, near the final process of the peripheral transistors TrP1 and the like, which have semiconductor layers containing silicon (Si) as channels. The post-annealing process is performed at, for example, about 400° C. The post-annealing process is used to supply hydrogen to the gate insulating films and channel interfaces of the peripheral transistors TrP1 and reduce interface state densities of the gate insulating films. This improves carrier mobility in the peripheral transistors TrP1 and obtains a satisfactory switching property.

In the post-annealing process according to this embodiment, the insulating layer 196 (FIG. 2) containing a large amount of hydrogen (H) becomes a supply source of hydrogen to the peripheral transistors TrP1 in some cases.

### Comparative Example

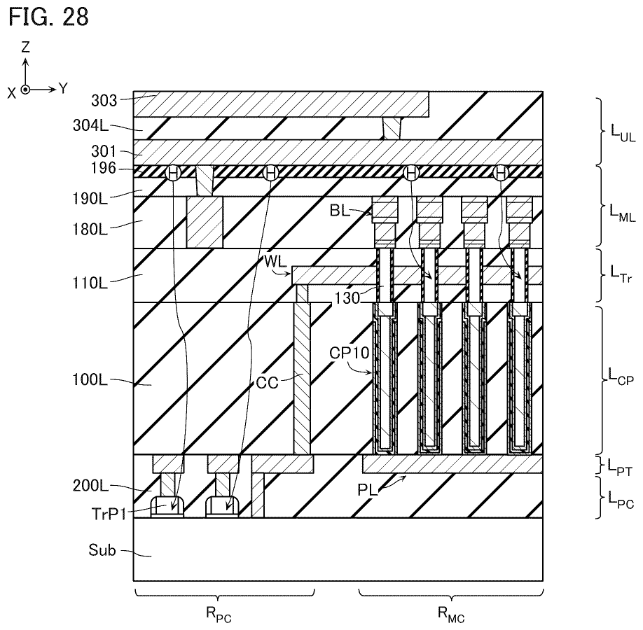

Next, with reference to FIG. 28, a semiconductor device according to a comparative example is described. FIG. 28 is a schematic cross-sectional view for describing a method of manufacturing the semiconductor device according to the comparative example.

In the semiconductor device according to the comparative example, the insulating layer group L similar to that in the peripheral region R_{PC} is also formed in the memory region R_{MC}. In the method of manufacturing the semiconductor device according to the comparative example, the insulating layer group H and the insulating layer group L are not created separately in the memory region R_{MC} and the peripheral region R_{PC}, respectively. In addition, in the semiconductor device according to the comparative example, the metal oxide layer 191 is not formed.

When the semiconductor device according to the comparative example is manufactured, the metal oxide layer 191 functioning as a hydrogen barrier layer is not formed, and further, the insulating layer group L, where hydrogen (H) is easily diffused, is formed in the memory region R_{MC}. This may cause a large amount of hydrogen (H) in the insulating layer 196 to reach the semiconductor layers 130 in the post-annealing process (FIG. 28). Accordingly, in the semiconductor layers 130 containing oxide semiconductors, for example, a donor-type OH defect occurs, a threshold of the select transistors ST shifts to a negative value, and a satisfactory switching property is not obtained in some cases.

### [Effects]

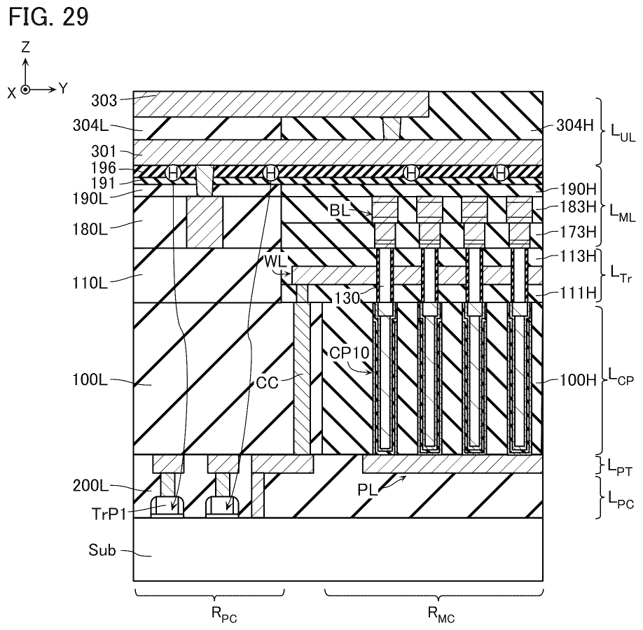

Next, effects of the semiconductor device according to this embodiment are described with reference to FIG. 29. FIG. 29 is a schematic cross-sectional view for describing the effects of the semiconductor device according to this embodiment.

The insulating layer group H, where the diffusion of hydrogen (H) is less likely to occur, is formed in the memory region R_{MC} of the semiconductor device according to this embodiment. In the method of manufacturing the semiconductor device according to this embodiment, the insulating layer group H and the insulating layer group L are created separately in the memory region R_{MC} and the peripheral region R_{PC}, respectively. In addition, in the semiconductor device according to this embodiment, the metal oxide layer 191 is formed.

When the semiconductor device according to this embodiment is manufactured, the metal oxide layer 191 functioning as a hydrogen barrier layer is formed, and further, the insulating layer group H, where hydrogen (H) is less likely to diffuse, is formed in the memory region R_{MC}. This can restrain hydrogen (H) in the insulating layer 196 from reaching the semiconductor layers 130 in the post-annealing process (FIG. 29). Accordingly, the shift of the threshold of the select transistors ST containing oxide semiconductors to a negative value is avoided, and a satisfactory switching property is obtained. In addition, since the insulating layer group L, where hydrogen (H) is easily diffused, is formed in the peripheral region R_{PC}, hydrogen (H) can be effectively supplied to the peripheral transistors TrP1 (FIG. 29).

When the semiconductor device according to this embodiment is manufactured, oxygen can be efficiently introduced to the semiconductor layers 130 by performing an oxidation process in a state where the metal oxide layer 191′ is exposed. Accordingly, a satisfactory switching property is obtained in the select transistors ST containing oxide semiconductors.

Therefore, with this configuration, the semiconductor device having excellent transistor characteristics both in the peripheral transistors TrP1 formed in the peripheral region R_{PC} and the select transistors ST formed in the memory region R_{MC} can be provided.

### Modification 1 of First Embodiment

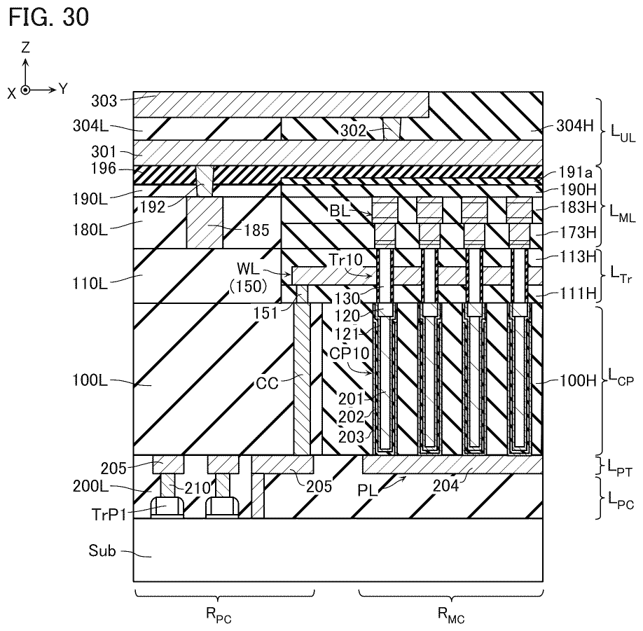

Next, with reference to FIG. 30, a modification 1 of the semiconductor device according to the first embodiment is described. FIG. 30 is a schematic cross-sectional view illustrating a part of a configuration of the semiconductor device according to the modification.

The semiconductor device according to the modification is basically configured similarly to the semiconductor device (FIG. 2) according to the first embodiment. However, in the semiconductor device (FIG. 30) according to the modification, the metal oxide layer 191 is not disposed, but instead, a metal oxide layer 191a is disposed.

For example, as illustrated in FIG. 30, the metal oxide layer 191a extends in the X-direction and the Y-direction, is disposed in the memory region R_{MC}, and is not disposed in the peripheral region R_{PC}.

The metal oxide layer 191a basically contains a material similar to that of the metal oxide layer 191 and has a similar function. At least a part of the metal oxide layer 191a functions as a layer to enhance the oxygen introduction efficiency to the semiconductor layers 130, for example, in the first oxidation process (FIG. 25) described above. In addition, together with the insulating layer group H, the metal oxide layer 191a functions as a hydrogen barrier layer that avoids the diffusion of hydrogen from the insulating layer 196 to the semiconductor layers 130, for example, in the post-annealing process described above.

### Modification 2 of First Embodiment

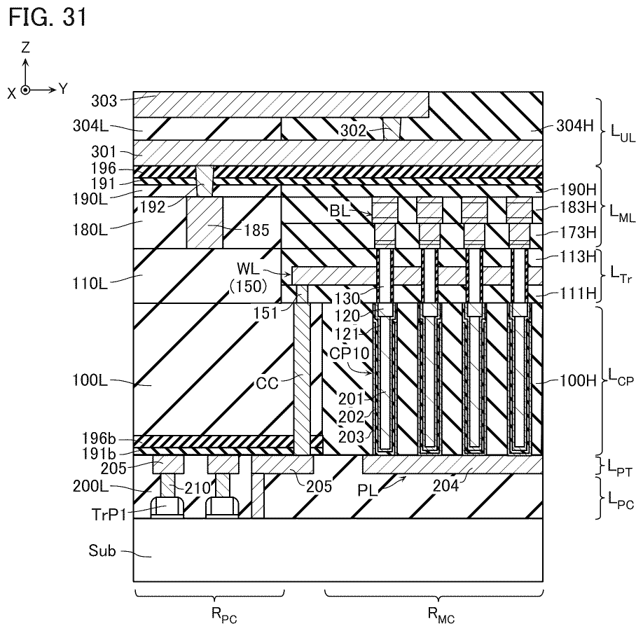

Next, with reference to FIG. 31, a modification 2 of the semiconductor device according to the first embodiment is described. FIG. 31 is a schematic cross-sectional view illustrating a part of a configuration of the semiconductor device according to the modification.

The semiconductor device according to the modification is basically configured similarly to the semiconductor device (FIG. 2) according to the first embodiment. However, in the semiconductor device (FIG. 31) according to the modification, a metal oxide layer 191b and an insulating layer 196b are disposed on the upper surface of the plate line layer L_{PT} in the peripheral region R_{PC}.

The metal oxide layer 191b basically contains a material similar to that of the metal oxide layer 191.

The insulating layer 196b basically contains a material similar to that of the insulating layer 196. The insulating layer 196b contains a large amount of hydrogen (H) in the material in some cases and becomes a supply source of hydrogen (H) in some cases. For example, in the post-annealing process described above, hydrogen (H) detaches not only from the insulating layer 196 but also from the insulating layer 196b. In this case, hydrogen (H) can be supplied also from the insulating layer 196b to the peripheral transistors TrP1 through the insulating layer 200L, where hydrogen (H) is easily diffused. The insulating layer 196b may have a film thickness similar to that of the insulating layer 196.

### Second Embodiment

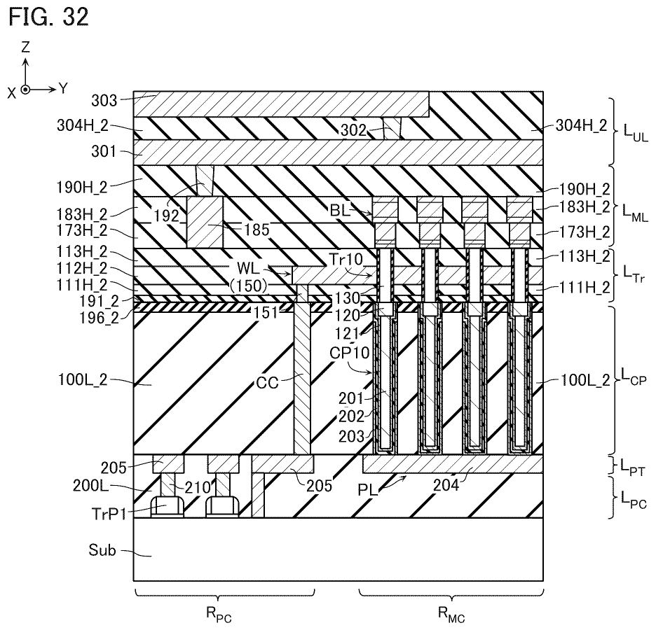

Next, with reference to FIG. 32, a semiconductor device according to a second embodiment is described. FIG. 32 is a schematic cross-sectional view illustrating a part of a configuration of the semiconductor device according to this embodiment. In the following description, the same reference numerals are attached to configurations similar to those in the first embodiment, and the explanation will be omitted.

The semiconductor device according to this embodiment is basically configured similarly to the semiconductor device (FIG. 2 to FIG. 6) according to the first embodiment. However, in the semiconductor device (FIG. 32) according to this embodiment, while the metal oxide layer 191 and the insulating layer 196 are not disposed, an insulating layer 196_2 is disposed on an uppermost layer of the capacitor layer L_{CP}, and a metal oxide layer 191_2 is disposed on an upper surface of the insulating layer 196_2.

In the capacitor layer L_{CP} in the memory region R_{MC}, an insulating layer 100L_2 is disposed, instead of the insulating layer 100H.

In the capacitor layer L_{CP} in the peripheral region R_{PC}, the insulating layer 100L_2 is disposed, instead of the insulating layer 100L. The insulating layer 100L_2 is continuously formed in the peripheral region R_{PC} and the memory region R_{MC}.

In the transistor layer L_{Tr} in the memory region R_{MC}, the insulating layer 111H, the insulating layers 112H, and the insulating layer 113H are not disposed, but instead, an insulating layer 111H_2, insulating layers 112H_2, and an insulating layer 113H_2 are disposed.

In the transistor layer L_{Tr} in the peripheral region R_{PC}, the insulating layer 110L is not disposed, but instead, the insulating layer 111H_2, the insulating layers 112H_2, and the insulating layer 113H_2 are disposed. The insulating layer 111H_2, the insulating layers 112H_2, and the insulating layer 113H_2 are each continuously formed in the peripheral region R_{PC} and the memory region R_{MC}.

In the wiring layer L_{ML} in the memory region R_{MC}, the insulating layer 173H, the insulating layer 183H, and the insulating layer 190H are not disposed, but instead, an insulating layer 173H_2, an insulating layer 183H_2, and an insulating layer 190H_2 are disposed.

In the wiring layer L_{ML} in the peripheral region R_{PC}, the insulating layer 180L and the insulating layer 190L are not disposed, but instead, the insulating layer 173H_2, the insulating layer 183H_2, and the insulating layer 190H_2 are disposed. The insulating layer 173H_2, the insulating layer 183H_2, and the insulating layer 190H_2 are each continuously formed in the peripheral region R_{PC} and the memory region R_{MC}.

In the wiring layer L_{UL} in the memory region R_{MC}, the insulating layer 304H is not disposed, but instead, an insulating layer 304H_2 is disposed.

In the wiring layer L_{UL} in the peripheral region R_{PC}, the insulating layer 304L is not disposed, but instead, the insulating layer 304H_2 is disposed. The insulating layer 304H_2 is continuously formed in the peripheral region R_{PC} and the memory region R_{MC}.

The insulating layer 111H_2, the insulating layers 112H_2, the insulating layer 113H_2, the insulating layer 173H_2, the insulating layer 183H_2, the insulating layer 190H_2, and the insulating layer 304H_2 are insulating layers belonging to the insulating layer group H described above.

The insulating layer 100L_2 is an insulating layer belonging to the insulating layer group L described above.

As described above, in the semiconductor device according to this embodiment, the insulating layers belonging to the insulating layer group H are formed in a region including the transistor layer L_{Tr}, the wiring layer L_{ML}, and the wiring layer L_{UL}, and the insulating layers belonging to the insulating layer group L are formed in a region including the capacitor layer L_{CP}, the plate line layer L_{PT}, and the peripheral circuit layer L_{PC}.

The metal oxide layer 191_2 basically contains a material similar to that of the metal oxide layer 191 and has a similar function. Together with the insulating layer group H, the metal oxide layer 191_2 functions as a hydrogen barrier layer that avoids the diffusion of hydrogen (H) from the insulating layer 196_2 to the semiconductor layers 130, for example, in the post-annealing process described above. The metal oxide layer 191_2 is not used for the first oxidation process (FIG. 25) described above.

The insulating layer 196_2 basically contains a material similar to that of the insulating layer 196. The insulating layer 196_2 contains a large amount of hydrogen (H) in the material in some cases and becomes a supply source of hydrogen (H) in some cases. For example, in the post-annealing process described above, hydrogen (H) detaches from the insulating layer 196_2. In this case, hydrogen (H) can be supplied to the peripheral transistors TrP1 through the insulating layer 100L_2 and the insulating layer 200L, through which hydrogen (H) easily passes. The insulating layer 196_2 may have a film thickness similar to that of the insulating layer 196.

### Manufacturing Method of Second Embodiment

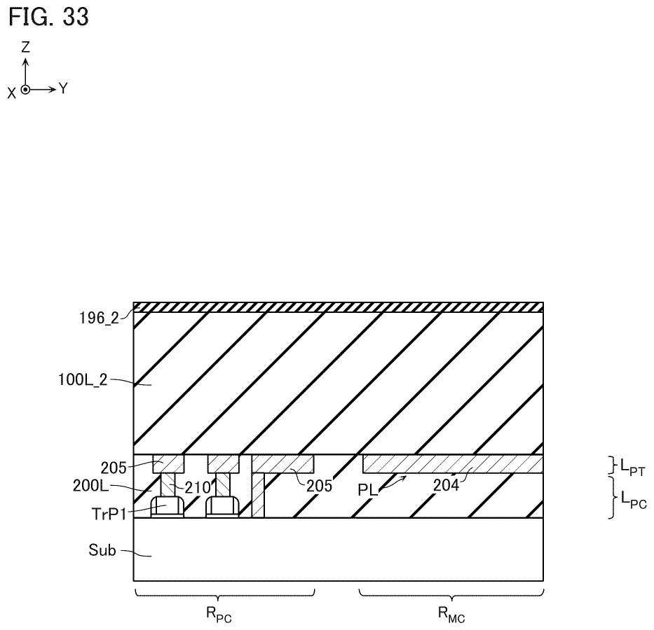

Next, with reference to FIG. 33 to FIG. 38, a method of manufacturing the semiconductor device according to this embodiment is described. The semiconductor device according to this embodiment is basically manufactured similarly to the semiconductor device according to the first embodiment. However, in the method of manufacturing the semiconductor device according to this embodiment, processes illustrated in FIG. 33 to FIG. 38 are performed next to the processes described with reference to FIG. 7 and FIG. 8.

In the process corresponding to FIG. 8, the insulating layer 100L_2 is formed instead of the insulating layer 100L′. This process is performed by, for example, the above-described low-temperature CVD or the like.

Next, for example, as illustrated in FIG. 33, the insulating layer 196_2 is formed on an upper surface of the insulating layer 100L_2. This process is performed by, for example, CVD or the like.

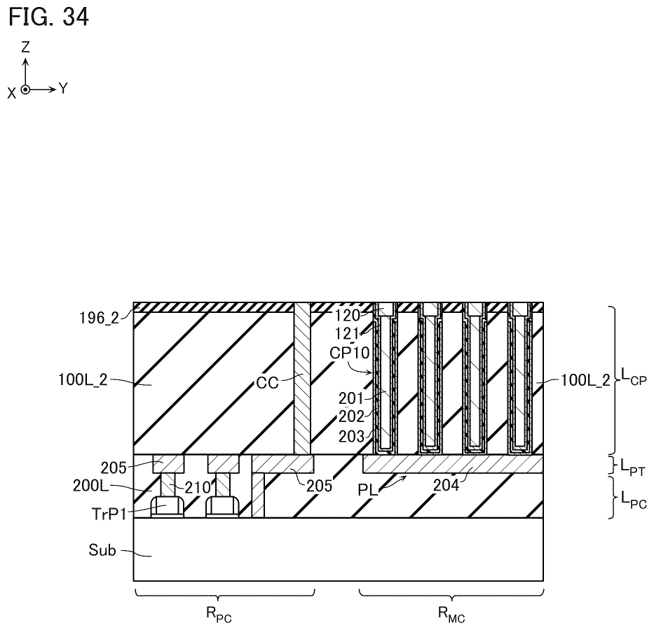

Next, for example, as illustrated in FIG. 34, openings are formed at respective positions corresponding to the electrodes CC and the capacitor structures CP10. In addition, a material similar to that of the electrodes CC is used to form films in the corresponding openings, and an unnecessary material formed on an upper surface of the insulating layer 196_2 is removed to form the electrodes CC. Further, the capacitor structures CP10 are formed by forming the conductive layer 203, the insulating layer 202, the conductive layer 121, the conductive layer 201, and the conductive layer 120 in sequence in the corresponding openings. This process is performed by, for example, RIE, CVD, and CMP or the like.

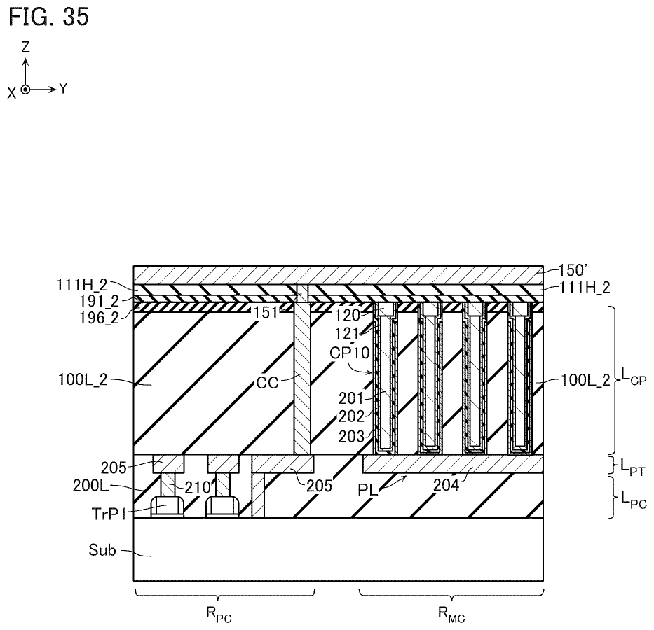

Next, for example, as illustrated in FIG. 35, the metal oxide layer 191_2 is formed on the upper surface of the capacitor layer L_{CP}. This process is performed by, for example, ALD, CVD, or the like. In addition, the insulating layer 111H_2 is formed on an upper surface of the metal oxide layer 191_2. This process is performed by, for example, the above-described high-temperature CVD. Further, the electrodes 151 that penetrate the insulating layer 111H_2 and the metal oxide layer 191_2 are formed, and the conductive layers 150′ containing a material similar to that of the conductive layers 150 are formed on upper surfaces of the insulating layer 111H_2 and the electrodes 151. This process is performed by, for example, RIE, CVD, and CMP or the like.

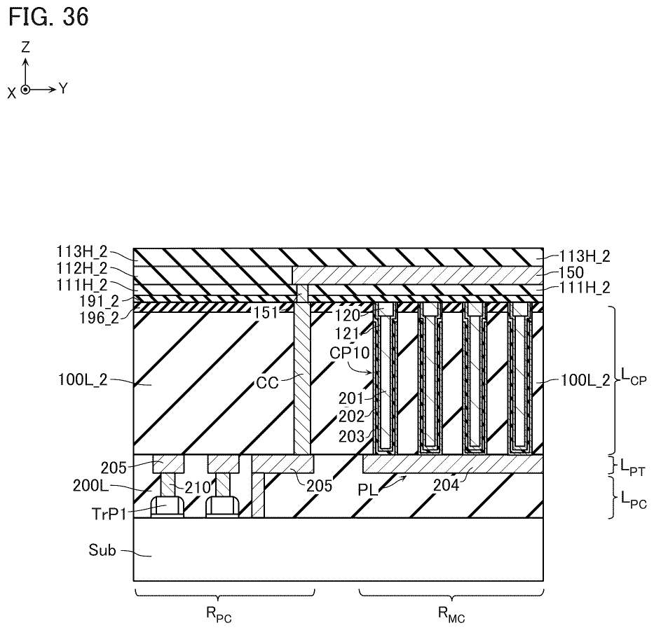

Next, for example, as illustrated in FIG. 36, the conductive layers 150 are formed by photolithography or the like. This process is performed by, for example, RIE or the like. In addition, the insulating layers 112H_2 are formed on the same layer as the plurality of conductive layers 150, and the insulating layer 113H_2 is formed on upper surfaces of the conductive layers 150 and the insulating layers 112H_2. This process is performed by, for example, the above-described high-temperature CVD and CMP or the like.

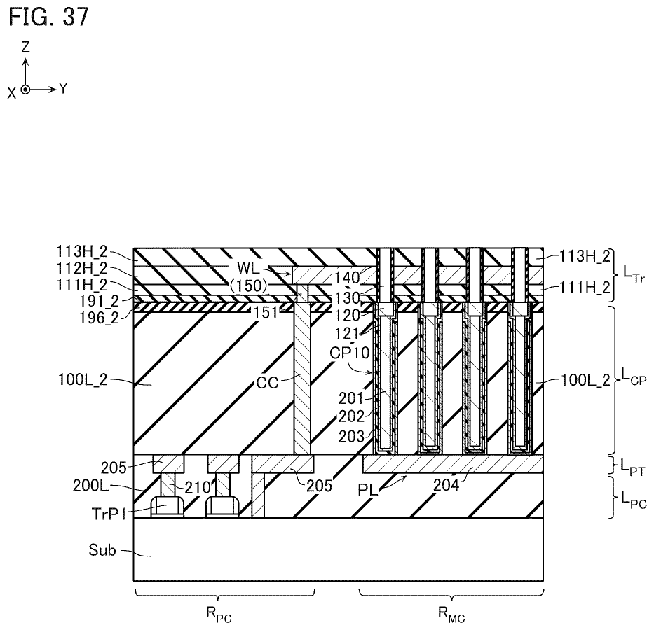

Next, for example, as illustrated in FIG. 37, openings are formed at positions corresponding to the insulating layers 140 and the semiconductor layers 130. Materials similar to those of the insulating layers 140 and the semiconductor layers 130 are used to form films in the respective openings, and unnecessary materials formed on an upper surface of the insulating layer 113H_2 are removed to form the insulating layers 140 and the semiconductor layers 130. This process is performed by RIE, CVD, CMP, and the like.

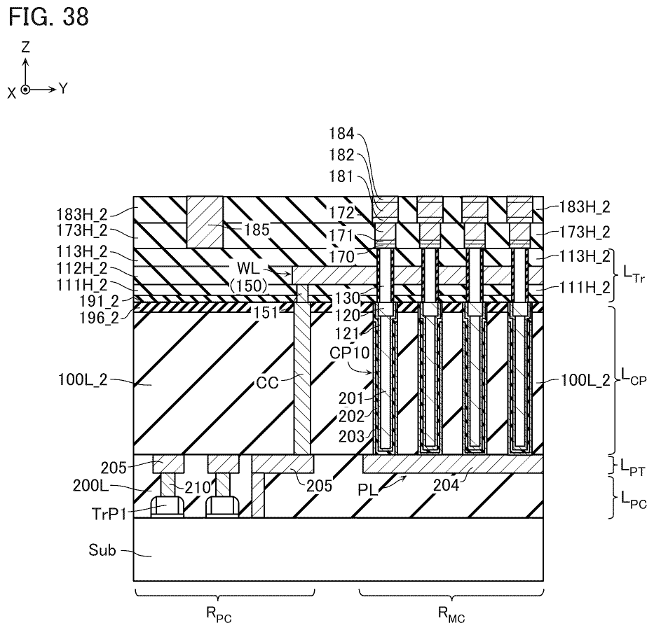

Next, for example, as illustrated in FIG. 38, the conductive layers 170, the conductive layers 171, the conductive layers 172, and the insulating layer 173H_2 are formed, similarly to the processes described with reference to FIG. 18 to FIG. 21. A layer illustrated as the insulating layer 173H′ in FIG. 19 to FIG. 21 corresponds to the insulating layer 173H_2. In addition, the conductive layers 181, the conductive layers 182, the conductive layers 184, and the insulating layer 183H_2 are formed. A layer illustrated as the insulating layer 183H′ in FIG. 21 corresponds to the insulating layer 183H_2.

The wiring 185 may be formed by removing parts of the insulating layer 173H_2 and the insulating layer 183H_2, similarly to the process illustrated in FIG. 23. This process is performed by, for example, RIE, CVD, CMP, or the like. Further, the wiring 185 may be simultaneously formed in the respective processes of forming the conductive layers 170, the conductive layers 171, and the conductive layers 172 and forming the conductive layers 181, the conductive layers 182, and the conductive layers 184.

Next, the insulating layer 190H_2 is formed on upper surfaces of the structures illustrated in FIG. 38. This process is performed by, for example, the above-described high-temperature CVD. In addition, an opening is formed at a position corresponding to the electrode 192. A material similar to that of the electrode 192 is used to form a film in the opening, and an unnecessary material formed on an upper surface of the insulating layer 190H_2 is removed to form the electrode 192. This process is performed by RIE, CVD, and CMP or the like.

Next, the wiring layer L_{UL} (FIG. 32) is formed. In the formation of the wiring layer L_{UL} (FIG. 32), as an inter-wiring layer film, the insulating layer 304H_2 is formed in the memory region R_{MC} and the peripheral region R_{PC}. The process of forming the insulating layer 304H_2 is performed by, for example, the above-described high-temperature CVD or the like.

During the formation or after the formation of the wiring layer L_{UL}, the post-annealing process described above is performed. The semiconductor device according to the second embodiment is manufactured as described above.

### [Effects]

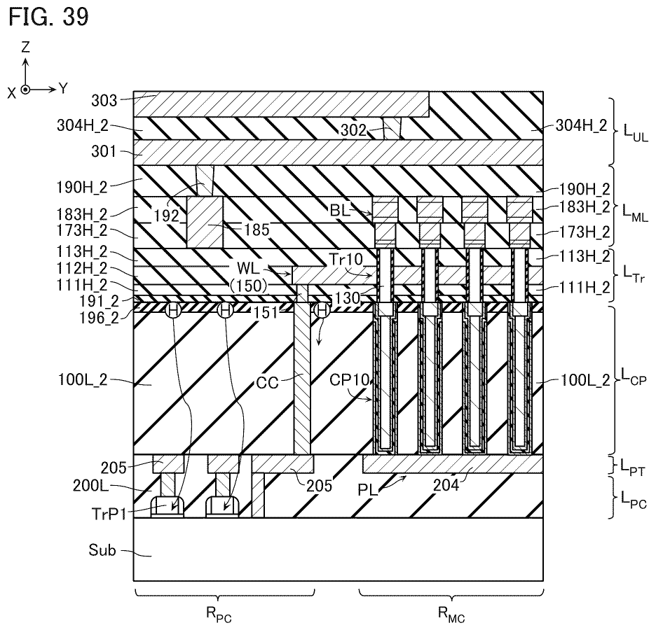

Next, effects of the semiconductor device according to this embodiment are described with reference to FIG. 39. FIG. 39 is a schematic cross-sectional view for describing the effects of the semiconductor device according to this embodiment.

In the semiconductor device according to this embodiment, the insulating layer group H, where the diffusion of hydrogen (H) is less likely to occur, is formed in a region including the transistor layer L_{Tr}, the wiring layer L_{ML}, and the wiring layer L_{UL} above the insulating layer 196_2 and the metal oxide layer 191_2.

When the semiconductor device according to this embodiment is manufactured, the metal oxide layer 191_2 functioning as a hydrogen barrier layer is formed on the upper surface of the insulating layer 196_2 containing a large amount of hydrogen, and the insulating layer group H, where hydrogen (H) is less likely to diffuse, and the semiconductor layers 130 are formed above the metal oxide layer 191_2. This can restrain hydrogen (H) in the insulating layer 196_2 from reaching the semiconductor layers 130 in the post-annealing process (FIG. 39). Accordingly, the shift of the threshold of the select transistors ST containing oxide semiconductors to a negative value is avoided, and a satisfactory switching property is obtained. In addition, since the insulating layer group L, where hydrogen (H) is easily diffused, is formed below the insulating layer 196_2, hydrogen (H) can be effectively supplied to the peripheral transistors TrP1 (FIG. 39).

Therefore, with this configuration, the semiconductor device having excellent transistor characteristics both in the peripheral transistors TrP1 formed in the peripheral region R_{PC} and the select transistors ST formed in the memory region R_{MC} can be provided.

### Third Embodiment

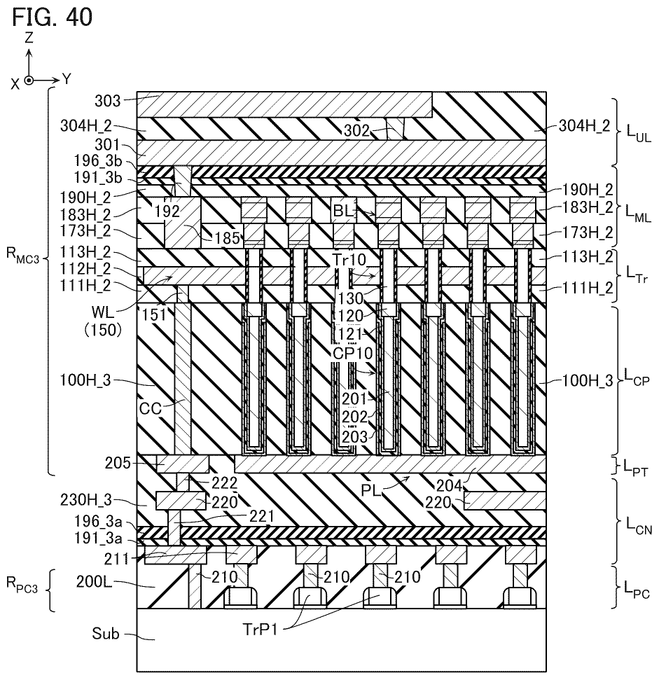

Next, with reference to FIG. 40, a semiconductor device according to a third embodiment is described. FIG. 40 is a schematic cross-sectional view illustrating a part of a configuration of the semiconductor device according to this embodiment. In the following description, the same reference numerals are attached to configurations similar to those in the first and second embodiments, and the explanation will be omitted.

The semiconductor device according to this embodiment is basically configured similarly to the semiconductor device (FIG. 32) according to the second embodiment and manufactured by a manufacturing method similar to those of the first and second embodiments. However, the semiconductor device (FIG. 40) according to this embodiment does not include the memory region R_{MC} or the peripheral region R_{PC} (FIG. 32) arranged in the Y-direction, but instead includes a memory region R_{MC3} and a peripheral region R_{PC3} (FIG. 40) arranged in the Z-direction on the substrate Sub. A connection layer LN is disposed between the memory region R_{MC3} and the peripheral region R_{PC3}.

The transistor layer L_{Tr}, the wiring layer L_{ML}, the wiring layer L_{UL}, the capacitor layer L_{CP}, and the plate line layer L_{PT}, which are similar to those of the semiconductor device (FIG. 32) according to the second embodiment, are disposed in the memory region R_{MC3}. However, in the capacitor layer L_{CP}, the insulating layer 100L_2 is not disposed, but instead, an insulating layer 100H_3 is disposed. In addition, the metal oxide layer 191_2 and the insulating layer 196_2 are not disposed in the transistor layer L_{Tr} or the capacitor layer L_{CP}. Instead, a metal oxide layer 191_3b and an insulating layer 196_3b are disposed on an upper surface of the insulating layer 190H_2.

The insulating layer 100H_3 is an insulating layer belonging to the insulating layer group H described above.

The peripheral circuit layer L_{PC} similar to that of the semiconductor device (FIG. 32) according to the second embodiment is disposed in the peripheral region R_{PC3}. However, in the peripheral circuit layer L_{PC} of the peripheral region R_{PC3}, a plurality of peripheral transistors TrP1 are disposed even at positions overlapping with the transistor structures Tr10 when viewed in the Z-direction.

In the connection layer L_{CN}, for example, wirings 211 connected to the electrodes 210 and a metal oxide layer 191_3a and an insulating layer 196_3a, which are disposed on upper surfaces of the wirings 211 and the insulating layer 200L, are disposed. In addition, in the connection layer L_{CN}, electrodes 221 connected to the wirings 211, wirings 220 connected to the electrodes 221, electrodes 222 connected to the wirings 220 and the conductive layers 205 are disposed, and an insulating layer 230H 3 is disposed therebetween.

The wirings 211, the electrodes 221, the wirings 220, and the electrodes 222 may contain, for example, copper (Cu), tungsten (W), or a stacked structure of titanium nitride (TiN) and tungsten (W). The electrodes 210, the wirings 211, the electrodes 221, the wirings 220, and the electrodes 222 function as connection layers electrically connecting the peripheral region R_{PC3} to the memory region R_{MC3}.

The insulating layer 230H 3 is an insulating layer belonging to the insulating layer group H described above.

The metal oxide layer 191_3a and the metal oxide layer 191_3b basically contain a material similar to that of the metal oxide layer 191 and have a similar function. However, the metal oxide layer 191_3a is not used for the first oxidation process (FIG. 25) described above. A part of the metal oxide layer 191_3b may be used for the first oxidation process (FIG. 25) described above. In addition, together with the insulating layer group H, the metal oxide layer 191_3b functions as a hydrogen barrier layer that avoids the diffusion of hydrogen (H) from the insulating layer 196_3b to the semiconductor layers 130, for example, in the post-annealing process described above. The metal oxide layer 191_3a and the metal oxide layer 191_3b may have a film thickness similar to that of the metal oxide layer 191.

The insulating layer 196_3a and the insulating layer 196_3b basically contain a material similar to that of the insulating layer 196. The insulating layer 196_3a and the insulating layer 196_3b contain a large amount of hydrogen (H) in the material in some cases and become supply sources of hydrogen (H) in some cases. For example, in the post-annealing process described above, hydrogen (H) detaches from the insulating layer 196_3a and the insulating layer 196_3b. In this case, hydrogen (H) can be supplied from the insulating layer 196_3a to the peripheral transistors TrP1 through the insulating layer 200L, where hydrogen (H) is easily diffused. The insulating layer 196_3a and the insulating layer 196_3b may have a film thickness similar to that of the insulating layer 196.

### Manufacturing Method of Third Embodiment

The semiconductor device according to this embodiment is basically manufactured similarly to the semiconductor devices according to the first and second embodiments. However, in the method of manufacturing the semiconductor device according to this embodiment, a plurality of peripheral transistors TrP1 are formed even at positions overlapping with the transistor structures Tr10 when viewed in the Z-direction in the process described with reference to FIG. 7. In addition, after the formation of the peripheral circuit layer L_{PC}, the connection layer LEN is formed on the peripheral circuit layer L_{PC}. Next, the plate line layer L_{PT} is formed on an upper surface of the connection layer Low, and then, the memory region R_{MC3} is formed similarly to the processes described with reference to FIG. 33 to FIG. 38.

In the process corresponding to FIG. 33, the insulating layer 100H_3 is formed instead of the insulating layer 100L_2, and the insulating layer 196_2 is not formed. In the process corresponding to FIG. 35, the metal oxide layer 191_2 is not formed. In addition, after the process corresponding to FIG. 38, before the electrode 192 is formed, the metal oxide layer 191_3b and the insulating layer 196_3b are formed. After a part of the metal oxide layer 191_3b is formed, the first oxidation process described above may be performed similarly to the process described with reference to FIG. 25.

### [Effects]

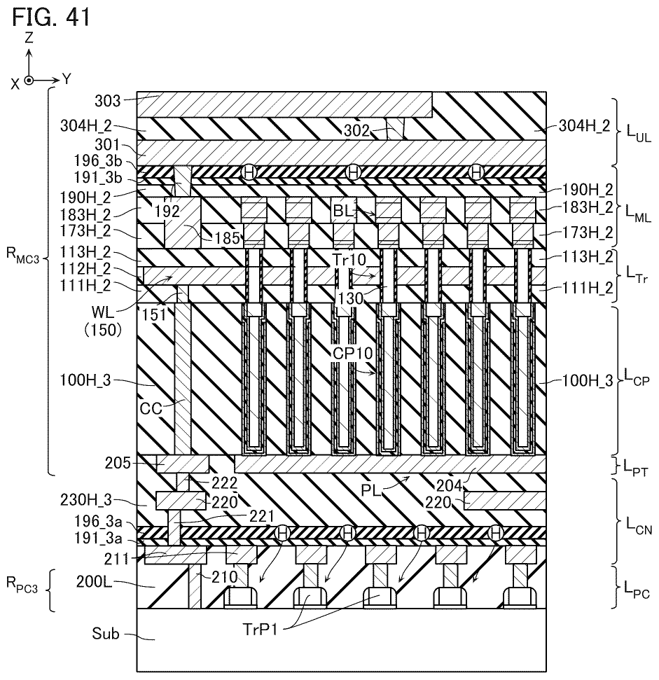

Next, effects of the semiconductor device according to this embodiment are described with reference to FIG. 41. FIG. 41 is a schematic cross-sectional view for describing the effects of the semiconductor device according to this embodiment.

In the semiconductor device according to this embodiment, the insulating layer group H, where the diffusion of hydrogen (H) is less likely to occur, is formed in the connection layer L_{CN} and the memory region R_{MC3} above the metal oxide layer 191_3a and the insulating layer 196_3a.

When the semiconductor device according to this embodiment is manufactured, the metal oxide layer 191_3b functioning as a hydrogen barrier layer is formed on a lower surface of the insulating layer 196_3b containing a large amount of hydrogen, and the insulating layer group H, where hydrogen (H) is less likely to diffuse, and the semiconductor layers 130 are formed below the metal oxide layer 191_3b. This can restrain hydrogen (H) in the insulating layer 196_3b from reaching the semiconductor layers 130 in the post-annealing process (FIG. 41). Accordingly, the shift of the threshold of the select transistors ST containing oxide semiconductors to a negative value is avoided, and a satisfactory switching property is obtained. In addition, since the insulating layer group L, where hydrogen (H) is easily diffused, is formed below the insulating layer 196_3a, hydrogen (H) can be effectively supplied to the peripheral transistors TrP1 (FIG. 41).

Therefore, with this configuration, the semiconductor device having excellent transistor characteristics both in the peripheral transistors TrP1 formed in the peripheral region R_{PC3} and the select transistors ST formed in the memory region R_{MC3} can be provided.

### Fourth Embodiment

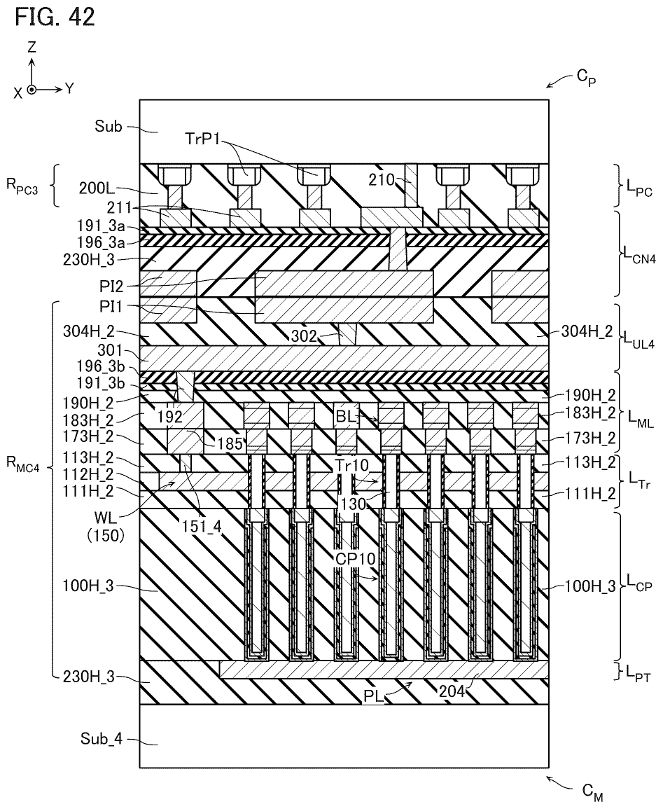

Next, with reference to FIG. 42, a semiconductor device according to a fourth embodiment is described. FIG. 42 is a schematic cross-sectional view illustrating a part of a configuration of the semiconductor device according to this embodiment. In the following description, the same reference numerals are attached to configurations similar to those in the first to third embodiments, and the explanation will be omitted.

The semiconductor device according to this embodiment includes a chip C_{M} and a chip C_{P}. The chip C_{M} includes a substrate Sub_4 and a memory region R_{MC4} formed on the substrate Sub_4. The chip C_{P} includes the peripheral region R_{PC3} formed on the substrate Sub and a connection layer L_{CN4} formed on an upper surface of the peripheral region R_{PC3}. The substrate Sub_4 or the substrate Sub may be removed.

The substrate Sub_4, for example, may contain P-type silicon (Si) containing P-type impurities, such as boron (B), or may be a substrate or the like containing another material of a glass substrate.

A plurality of bonding electrodes PI1 are disposed on an upper surface of the chip C_{M}. Additionally, a plurality of bonding electrodes PI2 are disposed on a lower surface of the chip C_{P}. Hereinafter, regarding the chip C_{M}, a surface on which the plurality of bonding electrodes PI1 are disposed is referred to as a front surface, and a surface on a substrate Sub_4 side is referred to as a back surface. Additionally, regarding the chip C_{P}, a surface on which the plurality of bonding electrodes PI2 are disposed is referred to as a front surface, and a surface on a substrate Sub side is referred to as a back surface. In the illustrated example, the back surface of the chip C_{P} is disposed above the front surface of the chip C_{P}, and the front surface of the chip C_{M} is disposed above the back surface of the chip C_{M}.

The chip C_{M} and the chip C_{P} are placed such that the front surface of the chip C_{M} is opposed to the front surface of the chip C_{P}. The respective plurality of bonding electrodes PI1 are disposed corresponding to the plurality of bonding electrodes PI2 and are placed at positions where the plurality of bonding electrodes PI1 can be bonded to the plurality of bonding electrodes PI2. The bonding electrodes PI1 and the bonding electrodes PI2 function as bonding electrodes for bonding the chip C_{M} and the chip C_{P} and electrically conducting them.

These plurality of bonding electrodes PI1 and plurality of bonding electrodes PI2 may include, for example, a stacked film of a barrier conductive film of, for example, titanium nitride (TiN) and a metal film of, for example, copper (Cu), or the like.

The transistor layer L_{Tr}, the wiring layer L_{ML}, the capacitor layer L_{CP}, and the plate line layer L_{PT}, which are similar to those in the memory region R_{MC3} (FIG. 40) according to the third embodiment, are disposed in the memory region R_{MC4}. However, instead of the wiring layer L_{UL} (FIG. 40), a wiring layer L_{UL4} (FIG. 42) is disposed in the memory region R_{MC4}.

The wiring layer L_{UL4} is basically disposed similarly to the wiring layer L_{UL}. However, in the wiring layer L_{UL4}, the plurality of bonding electrodes PI1 are disposed on a surface on a side far from the substrate Sub_4.

The connection layer L_{CN4} is basically disposed similarly to the connection layer LEN (FIG. 40). However, in the connection layer L_{CN4}, the plurality of bonding electrodes PI2 are disposed on a surface on a side far from the substrate Sub.

The word lines WL (150) in the memory region R_{MC4} are electrically connected to configurations in the peripheral region R_{PC3}, for example, via electrodes 151_4 and the like, and the bonding electrodes PI1, PI2, and the like. The electrodes 151_4 contain, for example, a material similar to that of the electrodes 151.

### Manufacturing Method of Fourth Embodiment

The semiconductor device according to this embodiment is manufactured by, for example, manufacturing each of a wafer on which the chip C_{M} is formed and a wafer on which the chip C_{P} is formed and then bonding the bonding electrodes PI1, PI2 on both wafers by, for example, direct bonding.

In the process of forming the chip C_{M}, for example, after the memory region R_{MC4} is formed on the substrate Sub_4 similarly to the process of forming the memory region R_{MC3} of the third embodiment (FIG. 40), the bonding electrodes PI1 are formed on an uppermost layer of the chip C_{M}.

In the process of forming the chip C_{P}, for example, after the peripheral region R_{PC3} is formed on the substrate Sub similarly to the process of forming the peripheral region R_{PC3} of the third embodiment (FIG. 40), the bonding electrodes PI2 are formed on an uppermost layer of the chip C_{P}.

In the method of manufacturing the semiconductor device according to this embodiment, the post-annealing process may be performed on the chip C_{P} before the chip C_{M} and the chip C_{P} are bonded. Alternatively, the post-annealing process may be performed after the chip C_{M} and the chip C_{P} are bonded.

### [Effects]

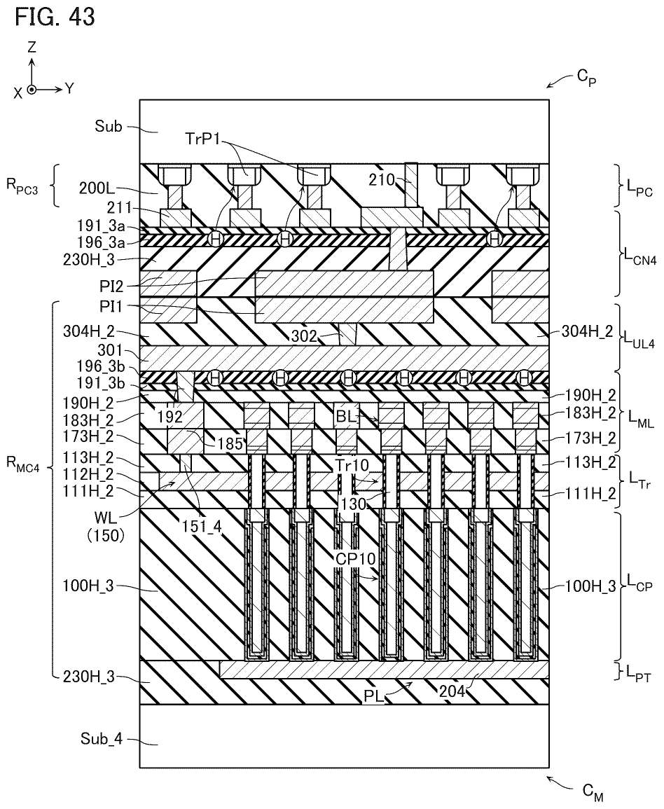

Next, effects of the semiconductor device according to this embodiment are described with reference to FIG. 43. FIG. 43 is a schematic cross-sectional view for describing the effects of the semiconductor device according to this embodiment.

In the semiconductor device according to this embodiment, the insulating layer group H, where the diffusion of hydrogen (H) is less likely to occur, is formed in the connection layer L_{CN4} and the memory region R_{MC4} below the insulating layer 196_3a containing a large amount of hydrogen (H) and the metal oxide layer 191_3a. In addition, the metal oxide layer 191_3b functioning as a hydrogen barrier layer is formed on the lower surface of the insulating layer 196_3b containing a large amount of hydrogen, and the insulating layer group H, where hydrogen (H) is less likely to diffuse, and the semiconductor layers 130 are formed below the metal oxide layer 191_3b.

This can restrain hydrogen (H) in the insulating layer 196_3a and the insulating layer 196_3b from reaching the semiconductor layers 130 even when the post-annealing process is performed after the chip C_{M} and the chip C_{P} are bonded (FIG. 43). Accordingly, the shift of the threshold of the select transistors ST containing oxide semiconductors to a negative value is avoided, and a satisfactory switching property is obtained. In addition, since the insulating layer group L, where hydrogen (H) is easily diffused, is formed above the insulating layer 196_3a, hydrogen (H) can be effectively supplied to the peripheral transistors TrP1.

Therefore, with this configuration, the semiconductor device having excellent transistor characteristics both in the peripheral transistors TrP1 formed in the peripheral region R_{PC3} and the select transistors ST formed in the memory region R_{MC4} can be provided.

### Modification of Fourth Embodiment

For the positions of the chip C_{M} and the chip C_{P} of the fourth embodiment, the chip C_{M} may be on an upper side, and the chip C_{P} may be on a lower side. When the chip C_{M} is positioned on the upper side, the substrate Sub_4 positioned on the upper side may be removed after it is manufactured.

### Other Embodiments

The semiconductor devices according to the first embodiment to the fourth embodiment have been described above. However, the semiconductor devices according to these embodiments are only examples, and a specific configuration, operations, and the like are adjustable as appropriate.

For example, in the above description, the metal oxide layer 191 and the insulating layer 196 (FIG. 2, FIG. 31), the metal oxide layer 191a and the insulating layer 196 (FIG. 30), the metal oxide layer 191b and the insulating layer 196b (FIG. 31), the metal oxide layer 191_2 and the insulating layer 196_2 (FIG. 32), the metal oxide layer 191_3a and the insulating layer 196_3a (FIG. 40, FIG. 42), and the metal oxide layer 191_3b and the insulating layer 196_3b (FIG. 40, FIG. 42) are each disposed to be mutually in contact. However, each of them need not be disposed to be mutually in contact, and another insulating layer may be disposed therebetween. Another insulating layer may be, for example, an insulating layer or the like containing silicon oxide (SiO₂), silicon nitride (SiN), or another material. When another insulating layer contains silicon nitride (SiN), it is provided with silicon nitride (SiN) by, for example, PVD and has a hydrogen (H) content of 1×10¹⁹/cm³ or less.

For example, in the above description, the example in which the capacitor Cap (FIG. 1) is connected to the select transistor ST (FIG. 1) is described. In this example, the shape, structure, and the like of the capacitor Cap are adjustable as appropriate.

Additionally, in the above description, the example in which the capacitor Cap (FIG. 1) is employed as the memory portion connected to the select transistor ST (FIG. 1) is described. However, the memory portion need not be the capacitor Cap. For example, the memory portion may contain any material including a ferroelectric material, a ferromagnet material, and a chalcogen material such as GeSbTe, and may store data using the characteristics of these materials. For example, in any of the structures described above, any of these materials may be included in the insulating layer between the electrodes forming the capacitor Cap.

The above description shows an example in which the semiconductor layer 130 that functions as the channel region of the select transistor ST (FIG. 1) extends in, for example, the Z-direction and has an approximately columnar shape. However, for example, the semiconductor layer 130 may have an approximately cylindrical shape extending in the Z-direction. Further, an insulating layer that has an approximately columnar shape extending in the Z-direction and contains silicon oxide (SiO₂) and the like may be disposed inside the semiconductor layer 130.

In the above description, the example in which the memory cell MC (FIG. 1) includes the select transistor ST containing oxide semiconductors and the capacitor Cap is described. However, the memory cell MC may include, for example, a semiconductor layer containing silicon (Si), a gate insulating film containing an electric charge accumulating film, and a gate electrode. The memory cell MC has a threshold voltage that changes according to an electric charge amount in the electric charge accumulating film. By supplying a large amount of hydrogen to the gate insulating film in the memory cell MC, the threshold voltage of the memory cell MC is easily shifted, and the reliability of the memory cell MC is reduced in some cases. In the example, the insulating layer group H may be disposed in a region where the memory cell MC is disposed, and the insulating layer group L may be disposed in a region where the peripheral circuit PC is disposed. In the configuration, since hydrogen (H) is less likely to pass through the insulating layer group H in the post-annealing process, hydrogen (H) reaching the gate insulating film of the memory cell MC can be avoided. In addition, since hydrogen (H) is easily diffused through the insulating layer group L, hydrogen (H) can be efficiently supplied to the peripheral transistors TrP1 in the peripheral circuit PC.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a substrate;
a first region disposed on one side in a first direction intersecting with a surface of the substrate with respect to the substrate;
a second region disposed to be arranged with the first region in the first direction or a second direction intersecting with the first direction on the one side in the first direction with respect to the substrate; and
a first insulating layer and a metal oxide layer disposed at a position farther from the substrate than the first region on the one side in the first direction, wherein
the first region includes:
a first transistor having a first semiconductor layer containing silicon (Si); and
a second insulating layer disposed between the first insulating layer and the first transistor and between the metal oxide layer and the first transistor,
the second region includes:
a second transistor having a second semiconductor layer containing an oxide semiconductor; and
a third insulating layer disposed between the first insulating layer and the second transistor and between the metal oxide layer and the second transistor,
the metal oxide layer contains at least one element selected from the group consisting of aluminum (Al), hafnium (Hf), zirconium (Zr), lanthanum (La), and yttrium (Y) and contains oxygen (O),
each of the second insulating layer and the third insulating layer contains silicon (Si) and oxygen (O), and
a density of the third insulating layer is higher than a density of the second insulating layer.

2. The semiconductor device according to claim 1, wherein
the oxide semiconductor contains at least one element selected from the group consisting of indium (In), gallium (Ga), zinc (Zn), magnesium (Mg), aluminum (Al), calcium (Ca), titanium (Ti), manganese (Mn), cadmium (Cd), and tin (Sn) and contains zinc (Zn) and oxygen (O).

3. The semiconductor device according to claim 1, wherein
the first insulating layer contains nitrogen (N) and silicon (Si).

4. The semiconductor device according to claim 1, further comprising:
a first wiring extending in the second direction and opposed to a part of the second semiconductor layer; and
a gate insulating film disposed between the second semiconductor layer and the first wiring, wherein
the second semiconductor layer extends in the first direction.

5. The semiconductor device according to claim 4, wherein
the third insulating layer surrounds a part of the second semiconductor layer in the second direction and a third direction intersecting with the first direction and the second direction.

6. The semiconductor device according to claim 4, further comprising
a second wiring extending in a third direction intersecting with the first direction and the second direction, wherein
the second wiring is electrically connected to the second semiconductor layer.

7. The semiconductor device according to claim 1, wherein
the first region and the second region are arranged in the second direction, and
the metal oxide layer is disposed at a position farther from the substrate than the second region on the one side in the first direction.

8. The semiconductor device according to claim 7, wherein
the second insulating layer is in contact with the first insulating layer, and
the metal oxide layer is disposed between the third insulating layer and the first insulating layer.

9. The semiconductor device according to claim 7, wherein
when viewed in the first direction,
the metal oxide layer is disposed between the second insulating layer and the first insulating layer, and
the metal oxide layer is disposed between the third insulating layer and the first insulating layer.

10. The semiconductor device according to claim 1, wherein
the first region and the second region are arranged in the first direction, and
the first insulating layer and the metal oxide layer are disposed between the first region and the second region.

11. The semiconductor device according to claim 1, wherein
the first insulating layer is in contact with the metal oxide layer.

12. The semiconductor device according to claim 1, wherein
a hydrogen (H) concentration of the third insulating layer is lower than a hydrogen (H) concentration of the second insulating layer.

13. The semiconductor device according to claim 1, further comprising
a capacitor electrically connected to the second semiconductor layer.

14. A semiconductor device comprising:
a substrate;
a first region disposed on one side in a first direction intersecting with a surface of the substrate with respect to the substrate;
a second region disposed to be arranged with the first region in the first direction or a second direction intersecting with the first direction on the one side in the first direction with respect to the substrate; and
a first insulating layer and a metal oxide layer disposed at a position farther from the substrate than the first region on the one side in the first direction, wherein
the first region includes:
a first transistor having a first semiconductor layer containing silicon (Si); and
a second insulating layer disposed between the first insulating layer and the first transistor and between the metal oxide layer and the first transistor,
the second region includes:
a second transistor having a second semiconductor layer containing an oxide semiconductor; and
a third insulating layer disposed between the first insulating layer and the second transistor and between the metal oxide layer and the second transistor,
the metal oxide layer contains at least one element selected from the group consisting of aluminum (Al), hafnium (Hf), zirconium (Zr), lanthanum (La), and yttrium (Y) and contains oxygen (O),
each of the second insulating layer and the third insulating layer contains silicon (Si) and oxygen (O), and
a hydrogen (H) concentration of the third insulating layer is lower than a hydrogen (H) concentration of the second insulating layer.

15. The semiconductor device according to claim 14, wherein
the oxide semiconductor contains at least one element selected from the group consisting of indium (In), gallium (Ga), zinc (Zn), magnesium (Mg), aluminum (Al), calcium (Ca), titanium (Ti), manganese (Mn), cadmium (Cd), and tin (Sn) and contains zinc (Zn) and oxygen (O).

16. The semiconductor device according to claim 14, wherein
the first insulating layer contains nitrogen (N) and silicon (Si).

17. The semiconductor device according to claim 14, further comprising:
a first wiring extending in the second direction and opposed to a part of the second semiconductor layer; and
a gate insulating film disposed between the second semiconductor layer and the first wiring, wherein
the second semiconductor layer extends in the first direction.

18. The semiconductor device according to claim 17, wherein
the third insulating layer surrounds a part of the second semiconductor layer in the second direction and a third direction intersecting with the first direction and the second direction.

19. The semiconductor device according to claim 17, further comprising
a second wiring extending in a third direction intersecting with the first direction and the second direction, wherein
the second wiring is electrically connected to the second semiconductor layer.

20. The semiconductor device according to claim 14, further comprising
a capacitor electrically connected to the second semiconductor layer.
